(19) United States
(12) Patent Application Publication
(10) Pub. No.: US 2020/0366276 A1
(43) Pub. Date: Nov. 19, 2020

(54) DRIVER CIRCUIT

(71) Applicant: Sony Semiconductor Solutions Corporation, Kanagawa (JP)

(72) Inventor: Ryota Shinoda, Kanagawa (JP)

(21) Appl. No.: 16/768,353

(22) PCT Filed: Aug. 31, 2018
(86) PCT No.: PCT/JP2018/032436

§ 371 Date: May 29, 2020

(30) Foreign Application Priority Data
Dec. 7, 2017 (JP) 2017-234824

(51) Int. Cl. H03K 3/012; H03K 17/08

(52) U.S. Cl. CPC H03K 3/012; H03K 17/08

(57) ABSTRACT

[Problem to be Solved] To make it possible to achieve both reduction in return loss and increase in resistance to an electro-static discharge.

[Solution] A driver circuit including: a first transistor including a control terminal, a first terminal, and a second terminal; a second transistor coupled to the first terminal of the first transistor in series via a predetermined load; a third transistor coupled to the second terminal of the first transistor in series to be interposed between the first transistor and any one of potentials including a first potential and a second potential; and an output terminal coupled between the second transistor and the load. The first potential and the second potential are different from each other. The third transistor is controlled to be in a conduction state while at least the first transistor and the second transistor are driven.

### TECHNICAL FIELD

The present disclosure relates to a driver circuit.

### BACKGROUND ART

In a case where a signal (e.g., serial signal) is transmitted between different circuits via a desired transmission path, the output impedance of the circuit sending the signal may be different from the input impedance of the circuit receiving the signal. In such a situation, for example, a so-called driver circuit is sometimes interposed between the circuit sending the signal and the circuit receiving the signal to match the output impedance and the input impedance (i.e., to perform impedance matching), thereby further increasing the transmission efficiency of the signal. For example, NPTL 1 discloses an example of a driver circuit that is applied for impedance matching.

### CITATION LIST

### Non-Patent Literature

NPTL 1: Kenichi Maruko, “A 1.296-to-5.184 Gb/s Transceiver with 2.4 mW/(Gb/s) Burst-mode CDR using Dual-Edge Injection-Locked Oscillator”, Solid-State Circuits Conference Digest of Technical Papers (ISSCC), 2010 IEEE International, (USA), Mar. 18, 2010, pp. 364 to 365

### SUMMARY OF THE INVENTION

### Problems to be Solved by the Invention

In contrast, in a situation in which a driver circuit is inserted to perform impedance matching, the portion where the driver circuit is inserted has discontinuous points of impedance, resulting in return loss in some cases due to the reflection of signals at the discontinuous points. Especially in recent years, so-called high frequency signals have been used in some cases as signals to be transmitted between circuits. Such a case may lead to return loss. In addition, a driver circuit includes an electronic circuit, and a situation may also be expected in which the occurrence of an electro-static discharge (ESD: Electro-Static Discharge) damages the electronic circuit.

Accordingly, the present disclosure proposes a driver circuit that makes it possible to achieve both reduction in return loss and increase in resistance to an electro-static discharge.

### Means for Solving the Problems

According to the present disclosure, there is provided a driver circuit including: a first transistor including a control terminal, a first terminal, and a second terminal; a second transistor coupled to the first terminal of the first transistor in series via a predetermined load; a third transistor coupled to the second terminal of the first transistor in series to be interposed between the first transistor and any one of potentials including a first potential and a second potential; and an output terminal coupled between the second transistor and the load. The first potential and the second potential are different from each other. The third transistor is controlled to be in a conduction state while at least the first transistor and the second transistor are driven.

### Effects of the Invention

According to the present disclosure as described above, the driver circuit is provided that makes it possible to achieve both reduction in return loss and increase in resistance to an electro-static discharge.

It is to be noted that the above-described effects are not necessarily limitative. Any of the effects indicated in this description or other effects that may be understood from this description may be exerted in addition to the above-described effects or in place of the above-described effects.

### BRIEF DESCRIPTION OF DRAWING

FIG. 1 is an explanatory diagram for describing an overview of a driver circuit.

FIG. 2 is an explanatory diagram for describing the overview of the driver circuit.

FIG. 3 is an explanatory diagram for describing an overview of ESD resistance of the driver circuit.

FIG. 4 is an explanatory diagram for describing an example of a configuration of a driver circuit according to a comparative example 1.

FIG. 5 is an explanatory diagram for describing an example of a configuration of a driver circuit according to a comparative example 2.

FIG. 6 is an explanatory diagram for describing an example of a circuit configuration of a driver circuit according to an embodiment of the present disclosure.

FIG. 7 is an explanatory diagram for describing an example of a circuit configuration of a driver circuit according to a modification example 1.

FIG. 8 is an explanatory diagram for describing an example of a configuration of a driver circuit according to a modification example 2.

FIG. 9 is an explanatory diagram for describing another example of the configuration of the driver circuit according to the modification example 2.

FIG. 10 is an explanatory diagram for describing another example of the configuration of the driver circuit according to the modification example 2.

FIG. 11 is an explanatory diagram for describing an example of a configuration of a driver circuit according to a modification example 3.

FIG. 12 is an explanatory diagram for describing another example of the configuration of the driver circuit according to the modification example 3.

FIG. 13 is an explanatory diagram for describing another example of the configuration of the driver circuit according to the modification example 3.

FIG. 14 is an explanatory diagram for describing an example of a configuration of a driver circuit according to a modification example 4.

FIG. 15 is an explanatory diagram for describing another example of the configuration of the driver circuit according to the modification example 4.

FIG. 16 is an explanatory diagram for describing another example of the configuration of the driver circuit according to the modification example 4.

FIG. 17 is an explanatory diagram for describing another example of the configuration of the driver circuit according to the modification example 4.

FIG. 18 is an explanatory diagram for describing another example of the configuration of the driver circuit according to the modification example 4.

FIG. 19 is an explanatory diagram for describing an example of a configuration of a driver circuit according to a modification example 5.

FIG. 20 is an explanatory diagram for describing an example of a configuration of a driver circuit according to a modification example 6.

FIG. 21 is an explanatory diagram for describing an application example of the driver circuit according to the embodiment.

FIG. 22 is an explanatory diagram for describing an application example of the driver circuit according to the embodiment.

FIG. 23 is an explanatory diagram for describing an example of a configuration of a driver circuit according to an application example 1.

FIG. 24 is an explanatory diagram for describing an example of a configuration of a driver circuit according to an application example 2.

FIG. 25 is an explanatory diagram for describing an example of a configuration of a driver circuit according to an application example 3.

FIG. 26 is an explanatory diagram for describing an example of a configuration of a driver circuit according to an application example 4.

FIG. 27 is an explanatory diagram for describing another example of the configuration of the driver circuit according to the application example 4.

FIG. 28 is an explanatory diagram for describing an example of a configuration of a driver circuit according to an application example 5.

FIG. 29 is an explanatory diagram for describing an example of an output of the driver circuit according to the application example 5.

### MODES FOR CARRYING OUT THE INVENTION

The following describes a preferred embodiment of the present disclosure in detail with reference to the accompanying drawings. It is to be noted that, in this description and the accompanying drawings, components that have substantially the same functional configuration are indicated by the same reference signs, and thus redundant description thereof is omitted.

It is to be noted that description is given in the following order.
1. Introduction
1.1. Overview of Driver Circuit
1.2. ESD Resistance
1.3. Study of Characteristics of Driver Circuit
2. Technical Features
2.1. Configurations
2.2. Modification Examples
2.3. Application Examples
3. Conclusion

### <<1. Introduction>>

### <1.1. Overview of Driver Circuit>

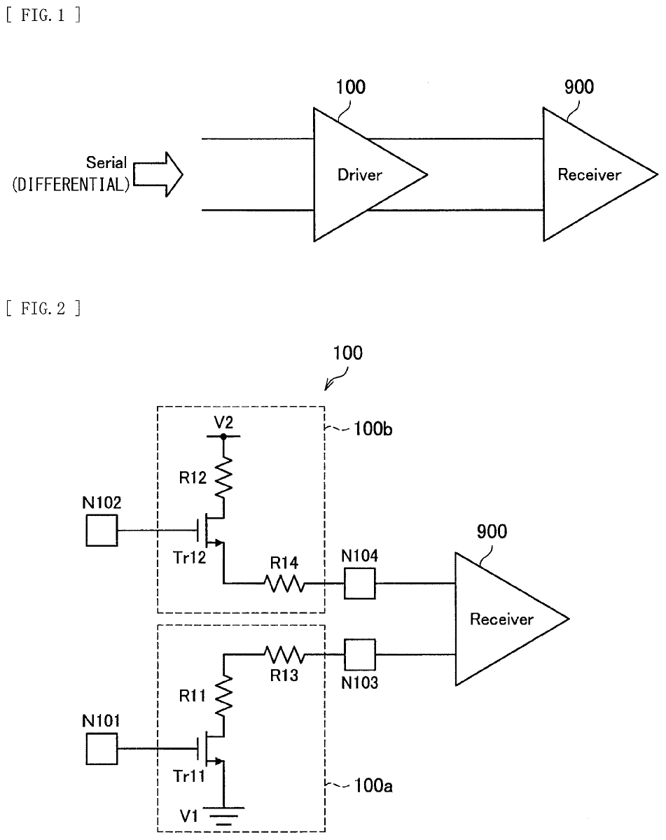

First, an overview of a driver circuit that is inserted into a transmission path to perform impedance matching is described with reference to FIGS. 1 and 2. Each of FIGS. 1 and 2 is an explanatory diagram for describing the overview of the driver circuit.

In a case where a signal (e.g., serial signal) is transmitted between different circuits via a desired transmission path, the output impedance of the circuit (that is also referred to as “transmitter (Transmitter)” below for as a matter of convenience) sending the signal may be different from the input impedance of the circuit (that is also referred to as “receiver (Receiver)” below as a matter of convenience) receiving the signal. In such a case, for example, a driver circuit is sometimes interposed between the transmitter and the receiver to perform impedance matching between the output impedance of the transmitter and the input impedance of the receiver, thereby further increasing the transmission efficiency of the signal.

For example, in the example illustrated in FIG. 1, a driver circuit 100 is interposed in a preceding stage of a receiver 900 to perform impedance matching between the input side (i.e., preceding stage of the driver circuit 100) of the driver circuit 100 and the output side (i.e., subsequent stage of the driver circuit 100) of the driver circuit 100 with the driver circuit 100 serving as a base point.

Here, an example of a schematic configuration of the driver circuit 100 is described with reference to FIG. 2. In the example illustrated in FIG. 2, the driver circuit 100 includes circuit groups 100a and 100b.

For example, the circuit group 100a performs impedance matching between a terminal N101 side (input side) and a terminal N103 side (output side). Specifically, the circuit group 100a includes a transistor Tr11 and resistors R11 and R13. The transistor Tr11 is configured, for example, as an N-type MOS transistor. The source terminal side of the transistor Tr11 is electrically coupled to a first potential V1 (e.g., ground). In addition, the drain terminal side of the transistor Tr11 is electrically coupled to the terminal N103 via the resistors R11 and R13. In addition, the base terminal of the transistor Tr11 is electrically coupled to the terminal N101. When a signal transmitted from a transmitter (not illustrated) is inputted to the terminal N101 in such a configuration, the signal drives the transistor Tr11 to bring the transistor Tr11 into a conduction state. This causes a signal (i.e., signal corresponding to the potential of the terminal N103) corresponding to a potential difference between the potential V1 and the terminal N103 to be outputted from the terminal N103 and inputted to the receiver 900. It is to be noted that the impedance of the output side is determined, for example, by the transistor Tr11, the potential V1, the resistor R11, and the resistor R13. Therefore, it is also possible to adjust the impedance of the output side, for example, by selectively changing any of the potential V1, the resistor R11, or the resistor R13. In addition, it is also possible to adjust the impedance of the output side by adjusting the impedance of the transistor Tr11 itself. In this case, the impedance of the transistor Tr11 itself may be adjusted, for example, by selectively applying a transistor different in size as the transistor Tr11.

In addition, the circuit group 100b performs impedance matching between a terminal N102 side (input side) and a terminal N104 side (output side). Specifically, the circuit group 100b includes a transistor Tr12 and resistors R12 and R14. The transistor Tr12 is configured, for example, as an N-type MOS transistor. The drain terminal side of the transistor Tr12 is electrically coupled to a second potential V2 (e.g., power supply voltage) via the resistor R12. In addition, the source terminal side of the transistor Tr12 is electrically coupled to the terminal N104 via the resistor R14. In addition, the base terminal of the transistor Tr12 is electrically coupled to the terminal N102. When a signal transmitted from a transmitter (not illustrated) is inputted to the terminal N102 in such a configuration, the signal drives the transistor Tr12 to bring the transistor Tr12 into the conduction state. This causes a signal (i.e., signal corresponding to the potential of the terminal N104) corresponding to a potential difference between the potential V2 and the terminal N104 to be outputted from the terminal N104 and inputted to the receiver 900. It is to be noted that the impedance of the output side is determined, for example, by the transistor Tr12, the potential V2, the resistor R12, and the resistor R14. Therefore, it is also possible to adjust the impedance of the output side, for example, by selectively changing any of the potential V2, the resistor R12, or the resistor R14. In addition, it is also possible to adjust the impedance of the output side by adjusting the impedance of the transistor Tr12 itself. In this case, the impedance of the transistor Tr12 itself may be adjusted, for example, by selectively applying a transistor different in size as the transistor Tr12.

The overview of the driver circuit that is inserted into the transmission path to perform impedance matching has been described above with reference to FIGS. 1 and 2.

### 1.2. ESD Resistance

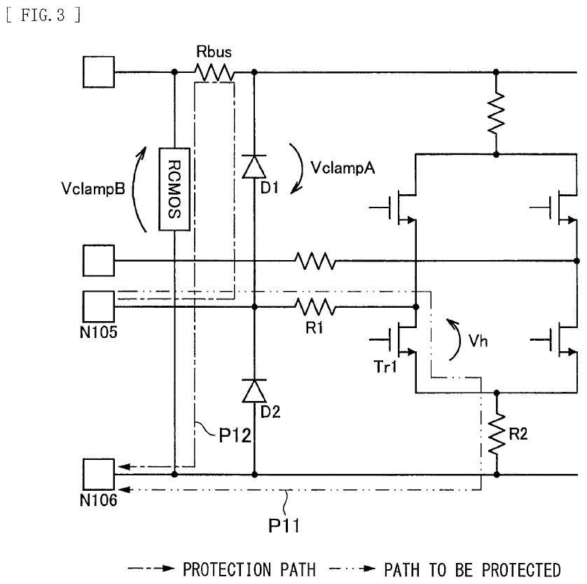

Next, an overview of the resistance (that is also referred to as “ESD resistance” below) of the driver circuit to an electro-static discharge is described. For example, FIG. 3 is an explanatory diagram for describing an overview of the ESD resistance of the driver circuit.

In FIG. 3, a reference sign Tr1 schematically refers to a portion of transistors included in a driver circuit. It is to be noted that a resistor R1, a transistor Tr1, and a resistor R2 are elements to be protected in this description. Therefore, a path P11 from a terminal N105 to a terminal N106 via the resistor R1, the transistor Tr1, and the resistor R2 is also referred to as “path to be protected”. Meanwhile, RCMOS and diodes D1 and D2 form a protection circuit for protecting the elements to be protected from ESD. In addition, a reference sign Rbus schematically refers to a parasitic resistor. Therefore, a path P12 from the terminal N105 to the terminal N106 via the diode D1, a parasitic resistor Rbus, and the RCMOS serves as a “protection path”.

Here, when a permissible voltage (that is also referred to as “permissible voltage to be protected” below) of the path P11 to be protected is represented as V_{P11}, the permissible voltage V_{P11} to be protected is expressed as a relational expression indicated below as (Expression 1).

[Expression 1]

V_{P11}=R1×Min_Imax+Vh+R2×Min_Imax (Expression 1)

In (Expression 1) above, Imax represents a current that is permitted to flow in an element such as a resistor or MOS included in a circuit to be protected (i.e., current that is permissible in the element). That is, Min Imax represents the minimum value of the currents Imax that are permitted by the respective elements (e.g., resistor R1, transistor Tr1, and resistor R2 illustrated in FIG. 3) included in the circuit to be protected. It is to be noted that the current value of a current permitted by each element tends to be smaller as the element has a smaller size. In addition, Vh represents the voltage between the source and drain of the transistor Tr1. That is, the permissible voltage V_{P11} to be protected also tends to be lower as an element included in the circuit to be protected has a smaller size.

In addition, when a voltage (that is also referred to as “protection path generation voltage” below) generated in the protection path P12 is represented as V_{P12}, the protection path generation voltage V_{P12} is expressed as a relational expression indicated below as (Expression 2).

[Expression 2]

V_{P12}=VclampA+VclampB+Rbus×Iesd (Expression 2)

In (Expression 1) above, Iesd represents a peak current flowing from the terminal N105 into the driver circuit in a case where a breakdown voltage at a desired ESD level is given. In addition, VclampA and VcalmpB respectively represent voltages applied to the diode D1 and the RCMOS.

In the example illustrated in FIG. 3, an element to be protected is protected by using ESD applied between the terminal N105 and the terminal N106 to allow a large current (i.e., peak current Iesd) flowing from the terminal N105 into the driver circuit to flow to the protection path P12 in such a configuration. Therefore, to achieve such an operation, it is desirable to design a drive circuit that, for example, allows the above-described permissible voltage V_{P11} to be protected and protection path generation voltage V_{P12} to satisfy a relational expression indicated below as (Expression 3).

V_{clampA}+VclampB+Rbus×Iesd<R1×Min_Imax+Vh+R2×Min_Imax (Expression 3)

The overview of the resistance (ESD resistance) of the driver circuit to an electro-static discharge has been described above with reference to FIG. 3.

### <1.3. Study of Characteristics of Driver Circuit>

Next, to facilitate the understanding of features of the driver circuit according to an embodiment of the present disclosure, an example of a configuration of the driver circuit is described as a comparative example, and technical problems of the driver circuit according to the present embodiment are then sorted out. It is to be noted that two patterns (the respective patterns are named a comparative example 1 and a comparative example 2) for an example of a configuration of the driver circuit are described in this description along with the features of the configuration.

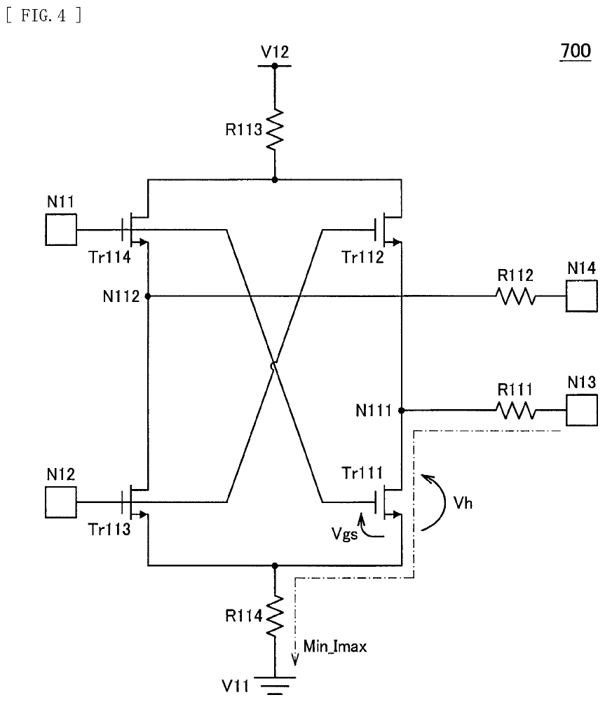

First, an example of a configuration of a driver circuit according to the comparative example 1 is described with reference to FIG. 4. FIG. 4 is an explanatory diagram for describing an example of a configuration of the driver circuit according to the comparative example 1. It is to be noted that the following description sometimes refers to the driver circuit according to the comparative example 1 as “driver circuit 700” to distinguish the driver circuit according to the comparative example 1 from the driver circuit according to the embodiment of the present disclosure.

As illustrated in FIG. 4, the driver circuit 700 includes transistors Tr111 to Tr114 and resistors R111 to R114. The transistors Tr111 and Tr112 are coupled in series. Specifically, the drain terminal of the transistor Tr111 is electrically coupled to the source terminal of the transistor Tr112. In addition, the source terminal of the transistor Tr111 is electrically coupled to a first potential V11 (e.g., ground) via the resistor R114. In addition, the drain terminal of the transistor Tr112 is electrically coupled to a second potential V12 (e.g., power supply voltage) via the resistor R113. In addition, a node N111 located between the drain terminal of the transistor Tr111 and the source terminal of the transistor Tr112 is electrically coupled to a terminal N13 via the resistor R111.

Similarly, the transistors Tr113 and Tr114 are coupled in series. Specifically, the drain terminal of the transistor Tr113 is electrically coupled to the source terminal of the transistor Tr114. In addition, the source terminal of the transistor Tr113 is electrically coupled to the first potential V11 (e.g., ground) via the resistor R114. In addition, the drain terminal of the transistor Tr114 is electrically coupled to the second potential V12 (e.g., power supply voltage) via the resistor R113. In addition, a node N112 located between the drain terminal of the transistor Tr113 and the source terminal of the transistor Tr114 is electrically coupled to a terminal N14 via the resistor R112.

In such a configuration, the transistors Tr111 to Tr114 are driven on the basis of signals inputted from terminals N11 and N12. For example, if the transistors Tr111 and Tr112 are brought into focus, a signal inputted from the terminal N11 is supplied to the base terminal of the transistor Tr111 and a signal inputted from the terminal N12 is supplied to the base terminal of the transistor Tr112. This causes a signal corresponding to the potential of the node N111 to be outputted to the outside of the driver circuit 700 via the terminal N13. In addition, if the transistors Tr113 and Tr114 are brought into focus, a signal inputted from the terminal N11 is supplied to the base terminal of the transistor Tr114 and a signal inputted from the terminal N12 is supplied to the base terminal of the transistor Tr113. This causes a signal corresponding to the potential of the node N112 to be outputted to the outside of the driver circuit 700 via the terminal N14.

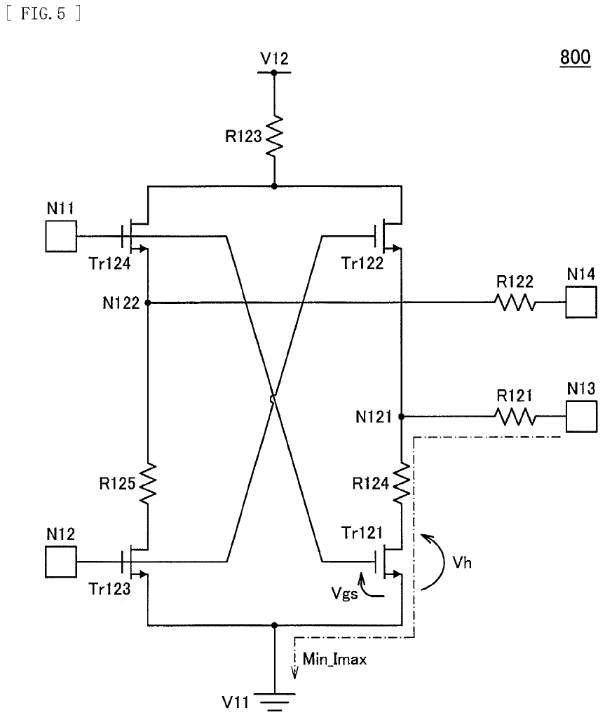

Next, an example of a configuration of a driver circuit according to the comparative example 2 is described with reference to FIG. 5. FIG. 5 is an explanatory diagram for describing an example of a configuration of the driver circuit according to the comparative example 2. It is to be noted that the following description sometimes refers to the driver circuit according to the comparative example 2 as “driver circuit 800” to distinguish the driver circuit according to the comparative example 2 from the driver circuit according to the embodiment of the present disclosure.

The driver circuit 800 according to the comparative example 2 is different from the driver circuit 700 according to the comparative example 1 described with reference to FIG. 4 in that resistors R124 and R125 are provided instead of the resistor R114 in the driver circuit 700.

Specifically, as illustrated in FIG. 5, the driver circuit 800 includes transistors Tr121 to Tr124 and resistors R121 to R125. It is to be noted that the transistors Tr121 to Tr124 correspond to the transistors Tr111 to Tr114 in the driver circuit 700 illustrated in FIG. 4.

The transistors Tr121 and Tr122 are coupled in series via the resistor R124. Specifically, the drain terminal of the transistor Tr121 is electrically coupled to the source terminal of the transistor Tr122 via the resistor R124. In addition, the source terminal of the transistor Tr121 is electrically coupled to the first potential V11 (e.g., ground). In addition, the drain terminal of the transistor Tr122 is electrically coupled to the second potential V12 (e.g., power supply voltage) via the resistor R123. In addition, a node N121 located between the resistor R124 and the source terminal of the transistor Tr122 is electrically coupled to the terminal N13 via the resistor R121.

Similarly, the transistors Tr123 and Tr124 are coupled in series via the resistor R125. Specifically, the drain terminal of the transistor Tr123 is electrically coupled to the source terminal of the transistor Tr124 via the resistor R125. In addition, the source terminal of the transistor Tr123 is electrically coupled to the first potential V11 (e.g., ground). In addition, the drain terminal of the transistor Tr124 is electrically coupled to the second potential V12 (e.g., power supply voltage) via the resistor R123. In addition, a node N122 located between the resistor R125 and the source terminal of the transistor Tr124 is electrically coupled to the terminal N14 via the resistor R122.

In such a configuration, the transistors Tr121 to Tr124 are driven on the basis of signals inputted from the terminals N11 and N12. For example, if the transistors Tr121 and Tr122 are brought into focus, a signal inputted from the terminal N11 is supplied to the base terminal of the transistor Tr121 and a signal inputted from the terminal N12 is supplied to the base terminal of the transistor Tr122. This causes a signal corresponding to the potential of the node N121 to be outputted to the outside of the driver circuit 800 via the terminal N13. In addition, if the transistors Tr123 and Tr124 are brought into focus, a signal inputted from the terminal N11 is supplied to the base terminal of the transistor Tr124 and a signal inputted from the terminal N12 is supplied to the base terminal of the transistor Tr123. This causes a signal corresponding to the potential of the node N122 to be outputted to the outside of the driver circuit 800 via the terminal N14.

Here, the driver circuit 700 according to the comparative example 1 and the driver circuit 800 according to the comparative example 2 are compared from the perspective of current consumption, return loss, and ESD resistance. As described above, in the driver circuit 700, the source terminal of the transistor Tr111 is electrically coupled to the first potential V11 via the resistor R114. In contrast, the driver circuit 800 is not provided with a component corresponding to the resistor R114, but is provided with the resistor R124 on the drain terminal side of the transistor Tr121 instead. Such a configuration allows the driver circuit 800 to obtain a larger voltage Vgs between the gate and source of the transistor Tr121 than the driver circuit 700 does. This allows the driver circuit 800 to apply an element smaller in size as the transistor Tr121 than the driver circuit 700 does, which makes it possible to further reduce the power consumption of the entire circuit.

In addition, the resistor R114 of the driver circuit 700 is coupled to the terminal (source terminal) side among the source terminal and drain terminal of the transistor Tr111. The terminal (source terminal) side is different from the terminal (drain terminal) to which the terminal N13 is coupled. Therefore, for example, in a situation in which a high frequency signal is used, the resistor R114 is less visible to the terminal N13 side because of the influence of the parasitic capacitance of the transistor Tr111, and the potential of the node N111 may be polarized. Such a state may appear, for example, as increase in return loss. In contrast, the resistor R124 of the driver circuit 800 is coupled to the terminal (drain terminal) among the source terminal and drain terminal of the transistor Tr121 to which the terminal N13 is coupled. Therefore, for example, even in a situation in which a high frequency signal is used, the resistor R124 is visible to the terminal N13 side irrespective of the influence of the parasitic capacitance of the transistor Tr121, and the potential of the node N121 is less likely to be polarized. That is, it is possible for the driver circuit 800 to further reduce return loss in using a high frequency signal than the driver circuit 700 does.

Meanwhile, the current value of the current Imax permissible in the transistor Tr121 is reduced by reducing the element size of the transistor Tr121 in the driver circuit 800. That is, the current value of the current Min Imax flowable between the terminal N13 and the first potential V11 is smaller in the driver circuit 800 than in the driver circuit 700. Therefore, the driver circuit 800 tends to have lower ESD resistance than that of the driver circuit 700.

In view of such situations, the present disclosure proposes an example of a driver circuit that makes it possible to achieve both reduction in return loss and increase in ESD resistance in using a high frequency signal.

### <<2. Technical Features>>

The following describes technical features of a driver circuit according to an embodiment of the present disclosure.

### <2.1. Configurations>

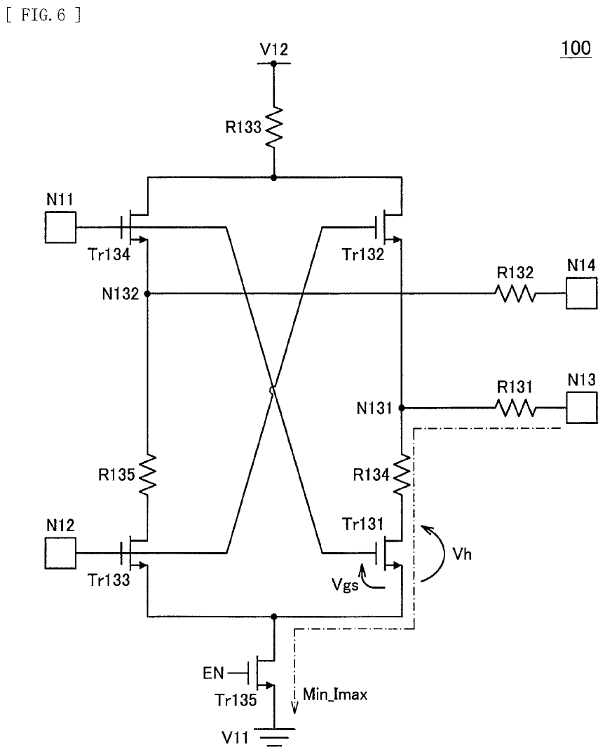

First, an example of the configuration of the driver circuit according to the embodiment of the present disclosure is described with reference to FIG. 6. FIG. 6 is an explanatory diagram for describing an example of a circuit configuration of the driver circuit according to the present embodiment.

As can been seen from a comparison between the configuration illustrated in FIG. 6 and the configuration of the driver circuit 800 described with reference to FIG. 5, the driver circuit 100 according to the present embodiment is different from the driver circuit 800 in that a transistor Tr135 is provided.

Specifically, as illustrated in FIG. 6, the driver circuit 100 includes transistors Tr131 to Tr134, resistors R131 to R135, and the transistor Tr135. It is to be noted that the transistors Tr131 to Tr134 and the resistors R131 to R135 correspond to the transistors Tr121 to Tr124 and the resistors R121 to R125 in the driver circuit 800 illustrated in FIG. 5. The components of the driver circuit 100 according to the present embodiment are thus described with a different portion from those of the driver circuit 800 in focus, but substantially similar portions as those of the driver circuit 800 are not described in detail.

As illustrated in FIG. 6, the respective source terminals of the transistors Tr131 and Tr133 are electrically coupled to the first potential V11 (e.g., ground) via the transistor Tr135. Specifically, the respective source terminals of the transistors Tr131 and Tr133 and the drain terminal of the transistor Tr135 are electrically coupled. In addition, the source terminal of the transistor Tr135 is electrically coupled to the first potential V11.

The transistor Tr135 is controlled on the basis of an enable signal EN to enter the conduction state. The enable signal EN is supplied to the base terminal. It is sufficient if the transistor Tr135 is controlled to be in the conduction state at all times, for example, while the driver circuit 100 is in operation. In other words, it is sufficient if the base terminal of the transistor Tr135 is supplied with the enable signal EN in a period in which the respective base terminals of the transistors Tr131 to Tr134 are able to receive signals (i.e., input signals of the driver circuit 100). It is desirable that the transistor Tr135 be controlled to be in the conduction state while at least the transistors Tr131 to Tr134 are driven.

It is to be noted that the transistor Tr135 corresponds to an example of a “third transistor” in the driver circuit 100. That is, the transistors Tr131 and Tr133 correspond to examples of a “first transistor”, and the transistors Tr132 and Tr134 correspond to examples of a “second transistor”. In addition, one (i.e., terminal on the first potential V11 side) of the terminals including the source terminal and drain terminal of the first transistor that is electrically coupled to the third transistor corresponds to an example of the “second terminal”, and the other terminal corresponds to an example of the “first terminal”. Similarly, one of the terminals including the source terminal and drain terminal of the second transistor that is electrically coupled to the second potential V12 corresponds to an example of the “third terminal”, and the other terminal corresponds to an example of a “fourth terminal”. In addition, the base terminal of the first transistor corresponds to an example of a “control terminal” of the first transistor. Similarly, the base terminal of the second transistor corresponds to an example of a “control terminal” of the second transistor.

Such a configuration makes it possible to consider the transistor Tr135 to be substantially equivalent to the resistor R114 in the driver circuit 700, for example, while the driver circuit 100 is in operation. This makes it possible in the driver circuit 100 to apply, as the transistors Tr131 and Tr133, transistors whose respective element sizes are similar to those of the transistors Tr111 and Tr113 in the driver circuit 700. In addition, in a case where the path between the terminal N13 and the first potential V11 is brought into focus, the driver circuits 700 and 800 each have one transistor interposed in the path, but the driver circuit 100 has two transistors interposed in the path. Such a characteristic allows the driver circuit 100 to have more increased ESD resistance than that of the driver circuit 800 according to the comparative example 2 illustrated in FIG. 5. Especially in each of the driver circuits as illustrated in FIGS. 4 to 6, the contribution rate of the characteristic of a transistor about ESD resistance tends to be high. This allows the driver circuit 100 to have much more increased ESD resistance than that of the driver circuit 800.

In addition, as with the driver circuit 800, a resistor R134 is provided to the driver circuit 100 to be interposed between the transistor Tr131 and the terminal N13. That is, even in a situation in which a high frequency signal is used, the resistor R134 is visible to the terminal N13 side irrespective of the influence of the parasitic capacitance of the transistor Tr131. It is to be noted that it is sufficient if the driver circuit 100 is configured to make the contribution rate of the transistor Tr135 to the setting of the potential of a node N131 lower than that of the resistor R134. This makes the potential of the node N131 more difficult to polarize even in a situation in which a high frequency signal is used, which makes it possible to further reduce return loss in using a high frequency signal than in the driver circuit 700.

It is to be noted that the current consumption of the driver circuit 100 is made substantially equivalent to that of the driver circuit 700 illustrated in FIG. 4 by performing control to keep the transistor Tr135 in the conduction state at all times while the driver circuit 100 is in operation.

As described above, the driver circuit 100 according to the present embodiment makes it possible to increase ESD resistance much more than that of each of the driver circuits 700 and 800. In addition, it is possible for the driver circuit 100 to further reduce return loss in using a high frequency signal than the driver circuit 700 does. That is, the driver circuit 100 according to the present embodiment makes it possible to achieve both reduction in return loss and increase in ESD resistance.

An example of the configuration of the driver circuit according to the embodiment of the present disclosure has been described above with reference to FIG. 6.

### 2.2. MODIFICATION EXAMPLES

Next, modification examples of the driver circuit according to the present embodiment are described.

### Modification Example 1

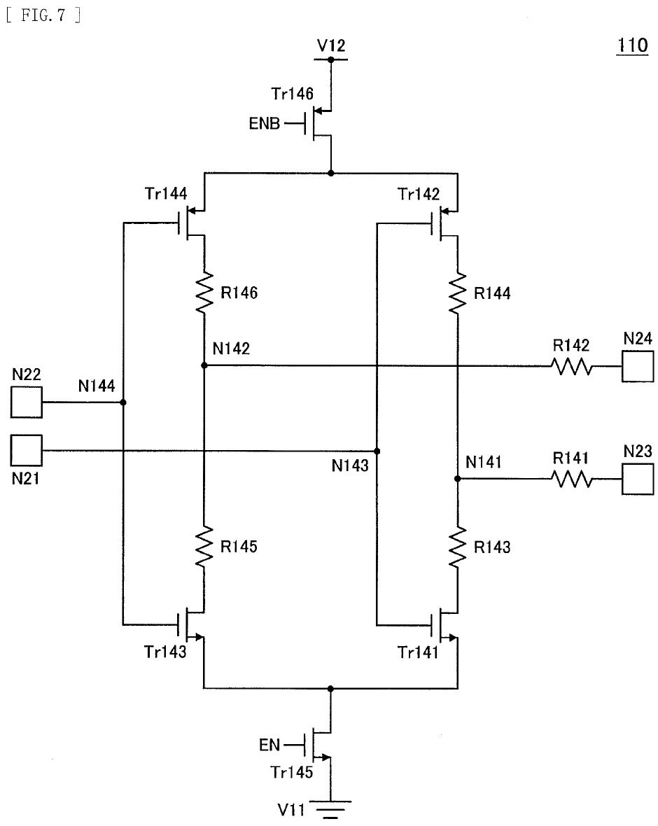

First, an example of a case where a transistor that is of a different type from the other transistors is applied to a portion of the respective transistors included in a driver circuit is described as a modification example 1. For example, FIG. 7 is an explanatory diagram for describing an example of a circuit configuration of a driver circuit according to the modification example 1. It is to be noted that the driver circuit illustrated in FIG. 7 is sometimes referred to as “driver circuit 110” to distinguish the driver circuit illustrated in FIG. 7 from the driver circuits according to the above-described embodiment and other modification examples.

Transistors Tr141 to Tr144 in the driver circuit 110 illustrated in FIG. 7 correspond to the transistors Tr131 to Tr134 in the driver circuit 100 illustrated in FIG. 6. As can be seen from a comparison between FIGS. 7 and 6, N-type MOS transistors are applied in the driver circuit 110 as the transistors Tr141 and Tr143 as with the transistors Tr131 and Tr133 in the driver circuit 100. Meanwhile, the driver circuit 110 is different from the driver circuit 100 in that P-type MOS transistors are applied as the transistors Tr142 and Tr144. In the driver circuit 100, N-type MOS transistors are applied as the transistors Tr132 and Tr134.

As illustrated in FIG. 7, the driver circuit 110 includes the transistors Tr141 to Tr144, resistors R141 to R146, and transistors Tr145 and Tr146. The transistors Tr141 and Tr142 are coupled in series. Specifically, the drain terminal of the transistor Tr141 is electrically coupled to the drain terminal of the transistor Tr142 via the resistors R143 and R144. In addition, the source terminal of the transistor Tr141 is electrically coupled to the first potential V11 (e.g., ground) via the transistor Tr145. In addition, the source terminal of the transistor Tr142 is electrically coupled to the second potential V12 (e.g., power supply voltage) via the transistor Tr146. In addition, a node N141 located between the resistor R143 and the resistor R144 is electrically coupled to a terminal N23 via the resistor R141.

Similarly, the transistors Tr143 and Tr144 are coupled in series. Specifically, the drain terminal of the transistor Tr143 is electrically coupled to the drain terminal of the transistor Tr144 via the resistors R145 and R146. In addition, the source terminal of the transistor Tr143 is electrically coupled to the first potential V11 (e.g., ground) via the transistor Tr145. In addition, the source terminal of the transistor Tr144 is electrically coupled to the second potential V12 (e.g., power supply voltage) via the transistor Tr146. In addition, a node N142 located between the resistor R145 and the resistor R146 is electrically coupled to a terminal N24 via the resistor R142.

The transistor Tr145 corresponds to the transistor Tr135 in the driver circuit 100 illustrated in FIG. 6, and is controlled on the basis of the enable signal EN to enter the conduction state. The enable signal EN is supplied to the base terminal. In addition, it is sufficient if the transistor Tr145 is controlled to be in the conduction state at all times, for example, while the driver circuit 110 is in operation. In addition, the transistor Tr146 is applied in the driver circuit 110 illustrated in FIG. 7 instead of the resistor R133 in the driver circuit 100. The transistor Tr146 is controlled as with the transistor Tr145. That is, the transistor Tr146 is controlled on the basis of an enable signal ENB to enter the conduction state. The enable signal ENB is supplied to the base terminal. In addition, it is sufficient if the transistor Tr146 is controlled to be in the conduction state at all times, for example, while the driver circuit 110 is in operation. It is to be noted that the driver circuit 110 may be provided with a component (i.e., resistor) substantially similar to the resistor R133 in the driver circuit 100 instead of the transistor Tr146.

In such a configuration, the transistors Tr141 to Tr144 are driven on the basis of signals inputted from terminals N21 and N22. Specifically, a signal inputted from the terminal N21 is split by a node N143, and then supplied to the respective base terminals of the transistors Tr141 and Tr142. This causes a signal corresponding to the potential of the node N141 to be outputted to the outside of the driver circuit 110 via the terminal N23. In addition, a signal inputted from the terminal N22 is split by a node N144, and then supplied to the respective base terminals of the transistors Tr143 and Tr144. This causes a signal corresponding to the potential of the node N142 to be outputted to the outside of the driver circuit 110 via the terminal N24.

An example of a case where a transistor that is of a different type from the other transistors is applied to a portion of the respective transistors included in a driver circuit has been described above as the modification example 1 with reference to FIG. 7.

### Modification Example 2

Next, another example of a configuration of the driver circuit according to the present embodiment is described as a modification example 2. In the above-described example indicating FIG. 7, an example of a configuration of the driver circuit in a case of two inputs and two outputs has been described. In contrast, a configuration of the driver circuit according to the present embodiment is not necessarily limited to only the example illustrated in FIG. 7.

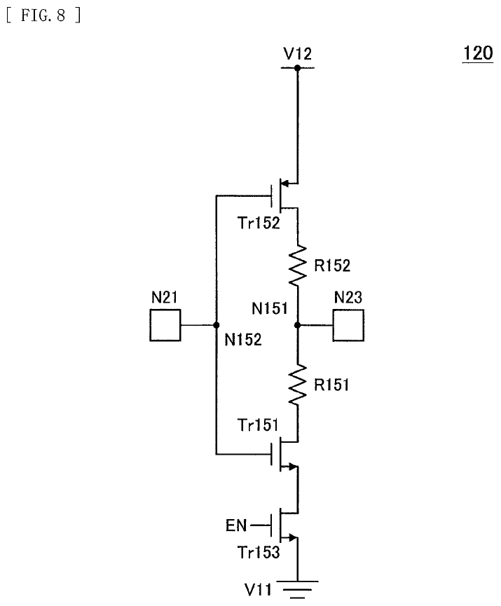

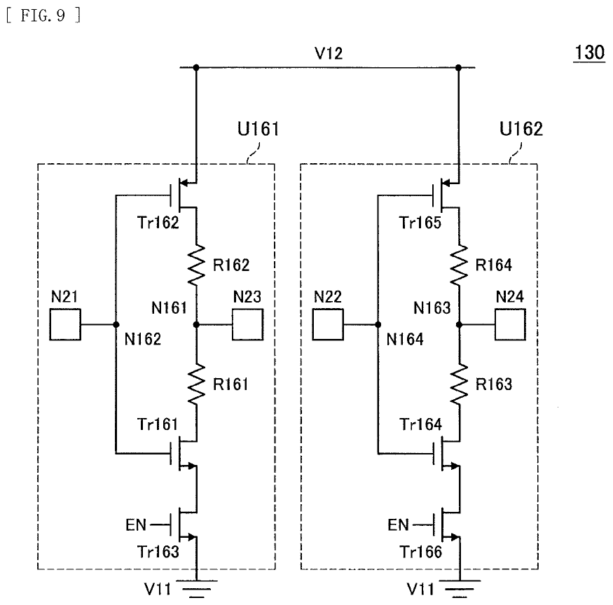

For example, FIG. 8 is an explanatory diagram for describing an example of a configuration of a driver circuit according to the modification example 2, and illustrates an example of a driver circuit configured to have one input and one output. It is to be noted that the driver circuit illustrated in FIG. 8 is sometimes referred to as “driver circuit 120” to distinguish the driver circuit illustrated in FIG. 8 from the driver circuits according to the above-described embodiment and other modification examples.

As illustrated in FIG. 8, the driver circuit 120 includes transistors Tr151 and Tr152, resistors R151 and R152, and a transistor Tr153. Each of the transistors Tr151 and Tr153 is configured, for example, as an N-type MOS transistor. In addition, the transistor Tr152 is configured, for example, as a P-type MOS transistor. The transistors Tr151 and Tr152 are coupled in series. Specifically, the drain terminal of the transistor Tr151 is electrically coupled to the drain terminal of the transistor Tr152 via the resistors R151 and R152. In addition, the source terminal of the transistor Tr151 is electrically coupled to the first potential V11 (e.g., ground) via the transistor Tr153. In addition, the source terminal of the transistor Tr152 is electrically coupled to the second potential V12 (e.g., power supply voltage). In addition, a node N151 located between the resistor R151 and the resistor R152 is electrically coupled to the terminal N23.

The transistor Tr153 corresponds to the transistor Tr135 in the driver circuit 100 illustrated in FIG. 6, and is controlled on the basis of the enable signal EN to enter the conduction state. The enable signal EN is supplied to the base terminal. It is sufficient if the transistor Tr153 is controlled to be in the conduction state at all times, for example, while the driver circuit 120 is in operation.

In such a configuration, the transistors Tr151 and Tr152 are driven on the basis of a signal inputted from the terminal N21. Specifically, a signal inputted from the terminal N21 is split by a node N152, and then supplied to the respective base terminals of the transistors Tr151 and Tr152. This causes a signal corresponding to the potential of the node N151 to be outputted to the outside of the driver circuit 120 via the terminal N23.

It is to be noted that the transistor Tr153 corresponds to an example of a “third transistor” in the driver circuit 120. That is, the transistor Tr151 corresponds to an example of a “first transistor”, and the transistor Tr152 corresponds to an example of a “second transistor”. In addition, one (i.e., terminal on the first potential V11 side) of the terminals including the source terminal and drain terminal of the first transistor that is electrically coupled to the third transistor corresponds to an example of the “second terminal”, and the other terminal corresponds to an example of the “first terminal”. Similarly, one of the terminals including the source terminal and drain terminal of the second transistor that is electrically coupled to the second potential V12 corresponds to an example of the “third terminal”, and the other terminal corresponds to an example of a “fourth terminal”. In addition, the base terminal of the first transistor corresponds to an example of a “control terminal” of the first transistor. Similarly, the base terminal of the second transistor corresponds to an example of a “control terminal” of the second transistor.

An example of a case where the driver circuit according to the modification example 2 is configured to have one input and one output has been described above with reference to FIG. 8 as an example of a configuration of the driver circuit.

It is to be noted that it is also possible to configure one multi-input and multi-output driver circuit by coupling, in parallel, the driver circuits 120 each of which is illustrated in FIG. 8. For example, FIG. 9 is an explanatory diagram for describing another example of the configuration of the driver circuit according to the modification example 2. It is to be noted that the driver circuit illustrated in FIG. 9 is sometimes referred to as “driver circuit 130” to distinguish the driver circuit illustrated in FIG. 9 from the driver circuits according to the above-described embodiment and other modification examples.

As illustrated in FIG. 9, the driver circuit 130 is configured by coupling circuit groups U161 and U162 in parallel. Each of the circuit groups U161 and U162 corresponds to the driver circuit 120 illustrated in FIG. 8. That is, transistors Tr161 to Tr163, resistors R161 and R162, and the terminals N21 and N23 in the circuit group U161 respectively correspond to the transistors Tr151 to Tr153, the resistors R151 and R152, and the terminals N21 and N23 in the driver circuit 120. Similarly, transistors Tr164 to Tr166, resistors R163 and R164, and the terminals N22 and N24 in the circuit group U162 respectively correspond to the transistors Tr151 to Tr153, the resistors R151 and R152, and the terminals N21 and N23 in the driver circuit 120.

It is to be noted that an example of a case where a 2-input and 2-output driver circuit is configured by coupling the two driver circuits 120 in parallel has been described as the example illustrated in FIG. 9, but the number of driver circuits 120 coupled in parallel is not necessarily limited to two. For example, one driver circuit may be configured by coupling the three or more driver circuits 120 in parallel. That is, it is also possible to configure an n-input and n-output driver circuit by coupling the n driver circuits 120 in parallel.

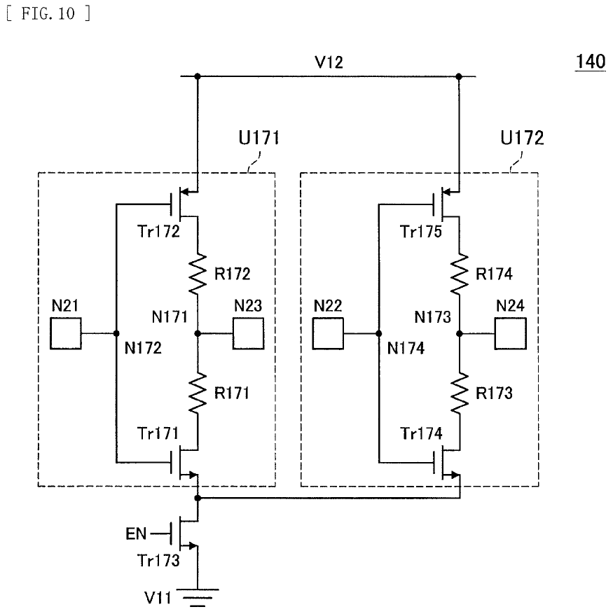

In addition, FIG. 10 is an explanatory diagram for describing another example of the configuration of the driver circuit according to the modification example 2. As the example illustrated in FIG. 10, an example of a case where the transistor Tr153 in the driver circuit 120 illustrated in FIG. 8 is shared between a plurality of circuit groups is demonstrated. It is to be noted that the driver circuit illustrated in FIG. 10 is sometimes referred to as “driver circuit 140” to distinguish the driver circuit illustrated in FIG. 10 from the driver circuits according to the above-described embodiment and other modification examples.

As illustrated in FIG. 10, the driver circuit 140 is configured by coupling circuit groups U171 and U172 in parallel and coupling a common transistor Tr173 to each of the circuit groups U171 and U172. Each of the circuit groups U171 and U172 corresponds to the components in the driver circuit 120 illustrated in FIG. 8 excluding the transistor Tr153. That is, transistors Tr171 and Tr172, resistors R171 and R172, and the terminals N21 and N23 in the circuit group U171 respectively correspond to the transistors Tr151 and Tr152, the resistors R151 and R152, and the terminals N21 and N23 in the driver circuit 120. Similarly, transistors Tr174 and Tr175, resistors R173 and R174, and terminals N25 and N24 in the circuit group U172 respectively correspond to the transistors Tr151 and Tr152, the resistors R151 and R152, and the terminals N21 and N23 in the driver circuit 120. In addition, the transistor Tr173 corresponds to the transistor Tr153 in the driver circuit 120.

In addition, the number of circuit groups (e.g., circuit groups U171 and U172) coupled in parallel is not also limited in the example illustrated in FIG. 10. That is, one driver circuit may be configured by coupling three or more circuit groups in parallel, and sharing the transistor Tr173 between the three or more circuit groups.

Another example of a configuration of the driver circuit according to the present embodiment has been described above as the modification example 2 with reference to FIGS. 8 to 10.

### Modification Example 3

Next, another example of a configuration of the driver circuit according to the present embodiment is described as a modification example 3. In the modification example 3, an example of a case where a component corresponding to the transistor Tr153 in the driver circuit 120 illustrated in FIG. 8 is provided on the second potential V12 (e.g., power supply voltage) side is described.

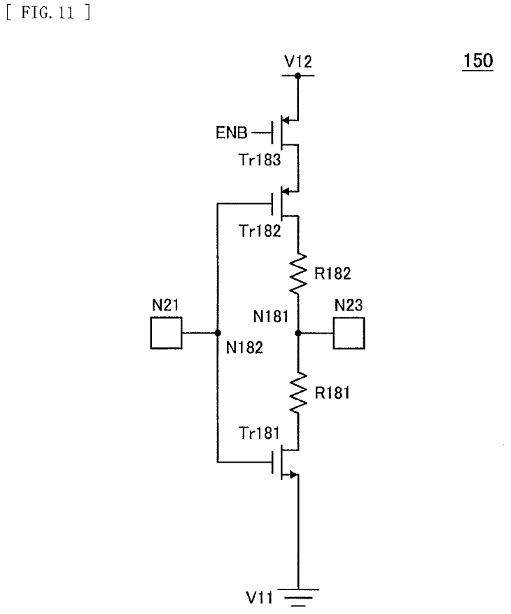

For example, FIG. 11 is an explanatory diagram for describing an example of a configuration of a driver circuit according to the modification example 3, and illustrates an example of a driver circuit configured to have one input and one output. It is to be noted that the driver circuit illustrated in FIG. 11 is sometimes referred to as “driver circuit 150” to distinguish the driver circuit illustrated in FIG. 11 from the driver circuits according to the above-described embodiment and other modification examples.

As illustrated in FIG. 11, the driver circuit 150 includes transistors Tr181 and Tr182, resistors R181 and R182, and a transistor Tr183. The transistor Tr181 is configured, for example, as an N-type MOS transistor. In addition, each of the transistors Tr182 and Tr183 is configured, for example, as a P-type MOS transistor. The transistors Tr181 and Tr182 are coupled in series. Specifically, the drain terminal of the transistor Tr181 is electrically coupled to the drain terminal of the transistor Tr182 via the resistors R181 and R182. In addition, the source terminal of the transistor Tr181 is electrically coupled to the first potential V11 (e.g., ground). In addition, the source terminal of the transistor Tr182 is electrically coupled to the second potential V12 (e.g., power supply voltage) via the transistor Tr183. In addition, a node N181 located between the resistor R181 and the resistor R182 is electrically coupled to the terminal N23.

The transistor Tr183 has a configuration that is substantially similar to that of the transistor Tr135 in the driver circuit 100 illustrated in FIG. 6, and is controlled on the basis of the enable signal ENB to enter the conduction state. The enable signal ENB is supplied to the base terminal. In addition, the transistor Tr183 is controlled substantially as with the transistor Tr135. That is, it is sufficient if the transistor Tr183 is controlled to be in the conduction state at all times, for example, while the driver circuit 150 is in operation.

In such a configuration, the transistors Tr181 and Tr182 are driven on the basis of a signal inputted from the terminal N21. Specifically, a signal inputted from the terminal N21 is split by a node N182, and then supplied to the respective base terminals of the transistors Tr181 and Tr182. This causes a signal corresponding to the potential of the node N181 to be outputted to the outside of the driver circuit 150 via the terminal N23.

It is to be noted that the transistor Tr183 corresponds to an example of a “third transistor” in the driver circuit 150. That is, the transistor Tr182 corresponds to an example of a “first transistor”, and the transistor Tr181 corresponds to an example of a “second transistor”. In addition, one (i.e., terminal on the second potential V12 side) of the terminals including the source terminal and drain terminal of the first transistor that is electrically coupled to the third transistor corresponds to an example of the “second terminal”, and the other terminal corresponds to an example of the “first terminal”. Similarly, one of the terminals including the source terminal and drain terminal of the second transistor that is electrically coupled to the first potential V11 corresponds to an example of the “third terminal”, and the other terminal corresponds to an example of a “fourth terminal”. In addition, the base terminal of the first transistor corresponds to an example of a “control terminal” of the first transistor. Similarly, the base terminal of the second transistor corresponds to an example of a “control terminal” of the second transistor.

An example of a case where the driver circuit according to the modification example 3 is configured to have one input and one output has been described above with reference to FIG. 11 as an example of a configuration of the driver circuit.

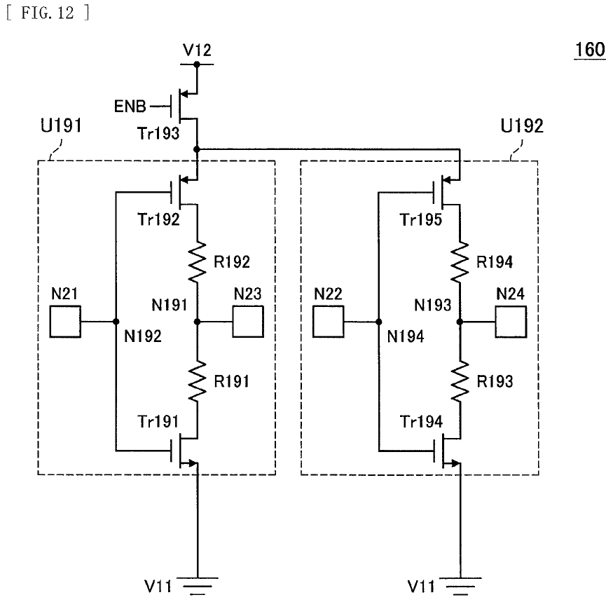

It is to be noted that it is also possible to configure one multi-input and multi-output driver circuit by coupling, in parallel, the driver circuits 150 each of which is illustrated in FIG. 11. For example, FIG. 12 is an explanatory diagram for describing another example of the configuration of the driver circuit according to the modification example 3. It is to be noted that the driver circuit illustrated in FIG. 12 is sometimes referred to as “driver circuit 160” to distinguish the driver circuit illustrated in FIG. 12 from the driver circuits according to the above-described embodiment and other modification examples.

As the example illustrated in FIG. 12, an example of a case where the transistor Tr183 in the driver circuit 150 illustrated in FIG. 11 is shared between a plurality of circuit groups is demonstrated. It is to be noted that the driver circuit illustrated in FIG. 12 is sometimes referred to as “driver circuit 160” to distinguish the driver circuit illustrated in FIG. 12 from the driver circuits according to the above-described embodiment and other modification examples.

As illustrated in FIG. 12, the driver circuit 160 is configured by coupling circuit groups U191 and U192 in parallel and coupling a common transistor Tr193 to each of the circuit groups U191 and U192. Each of the circuit groups U191 and U192 corresponds to the components in the driver circuit 150 illustrated in FIG. 11 excluding the transistor Tr183. That is, transistors Tr191 and Tr192, resistors R191 and R192, and the terminals N21 and N23 in the circuit group U191 respectively correspond to the transistors Tr181 and Tr182, the resistors R181 and R182, and the terminals N21 and N23 in the driver circuit 150. Similarly, transistors Tr194 and Tr195, resistors R193 and R194, and the terminals N22 and N24 in the circuit group U192 respectively correspond to the transistors Tr181 and Tr182, the resistors R181 and R182, and the terminals N21 and N23 in the driver circuit 150. In addition, the transistor Tr193 corresponds to the transistor Tr183 in the driver circuit 150.

In addition, an example of a case where a 2-input and 2-output driver circuit is configured by coupling the two circuit groups (e.g., circuit groups U191 and U192) in parallel has been described as the example illustrated in FIG. 12, but the number of circuit groups coupled in parallel is not necessarily limited to two. That is, one driver circuit may be configured by coupling three or more circuit groups in parallel, and sharing the transistor Tr193 between the three or more circuit groups.

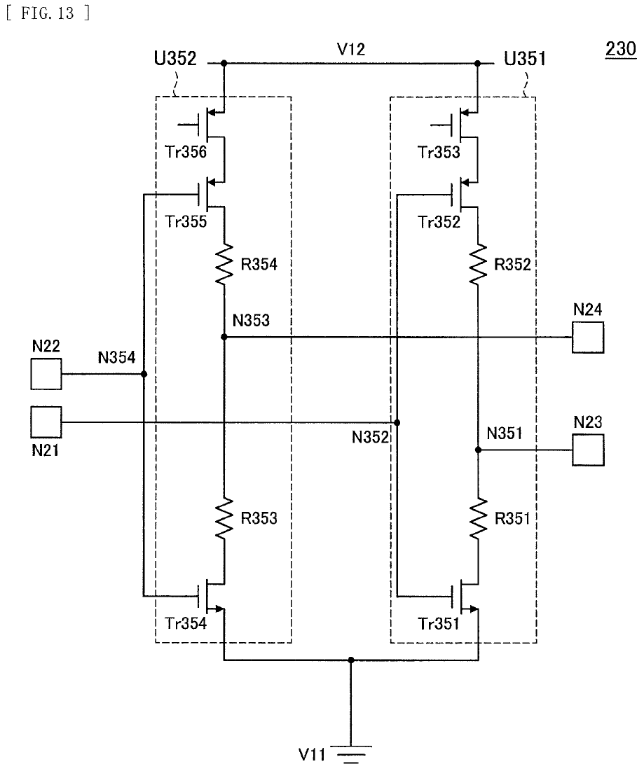

In addition, as with the driver circuit 130 described with reference to FIG. 9, one driver circuit may be configured by coupling the plurality of driver circuits 150 in parallel each of which is illustrated in FIG. 11. For example, FIG. 13 is an explanatory diagram for describing another example of the configuration of the driver circuit according to the modification example 3. It is to be noted that the driver circuit illustrated in FIG. 13 is sometimes referred to as “driver circuit 230” to distinguish the driver circuit illustrated in FIG. 13 from the driver circuits according to the above-described embodiment and other modification examples.

As illustrated in FIG. 13, the driver circuit 230 is configured by coupling circuit groups U351 and U352 in parallel. Each of the circuit groups U351 and U352 corresponds to the driver circuit 150 illustrated in FIG. 11. That is, transistors Tr351 to Tr353, resistors R351 and R352, and the terminals N21 and N23 in the circuit group U351 respectively correspond to the transistors Tr181 to Tr183, the resistors R181 and R182, and the terminals N21 and N23 in the driver circuit 150. Similarly, transistors Tr354 to Tr356, resistors R353 and R354, and the terminals N23 and N24 in the circuit group U352 respectively correspond to the transistors Tr181 to Tr183, the resistors R181 and R182, and the terminals N21 and N23 in the driver circuit 150.

It is to be noted that an example of a case where a 2-input and 2-output driver circuit is configured by coupling the two driver circuits 150 in parallel has been described as the example illustrated in FIG. 13, but the number of driver circuits 150 coupled in parallel is not necessarily limited to two. For example, one driver circuit may be configured by coupling the three or more driver circuits 150 in parallel.

Another example of a configuration of the driver circuit according to the present embodiment has been described above as the modification example 3, bringing into focus especially a case where a component corresponding to the transistor Tr153 in the driver circuit 120 illustrated in FIG. 8 is provided on the second potential V12 (e.g., power supply voltage) side.

### Modification Example 4

Next, another example of a configuration of the driver circuit according to the present embodiment is described as a modification example 4. In the modification example 4, an example of a case where a component corresponding to the transistor Tr153 is also provided on the second potential V12 (e.g., power supply voltage) side in the driver circuit 120 illustrated in FIG. 8 is described.

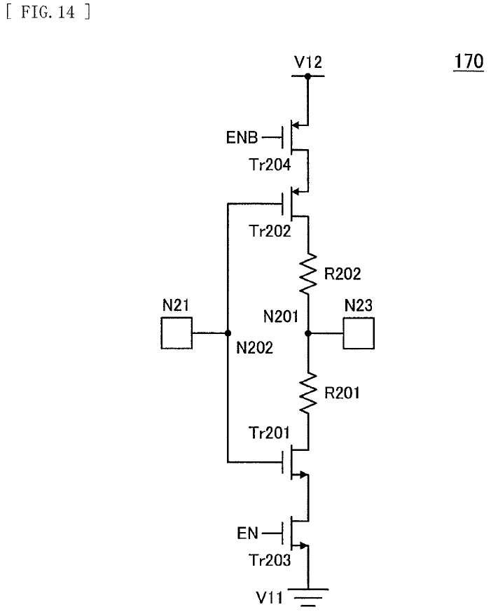

For example, FIG. 14 is an explanatory diagram for describing an example of a configuration of a driver circuit according to the modification example 4, and illustrates an example of a driver circuit configured to have one input and one output. It is to be noted that the driver circuit illustrated in FIG. 14 is sometimes referred to as “driver circuit 170” to distinguish the driver circuit illustrated in FIG. 14 from the driver circuits according to the above-described embodiment and other modification examples.

As illustrated in FIG. 14, the driver circuit 170 includes transistors Tr201 and Tr202, resistors R201 and R202, and transistors Tr203 and Tr204. Each of the transistors Tr201 and Tr203 is configured, for example, as an N-type MOS transistor. In addition, each of the transistors Tr202 and Tr204 is configured, for example, as a P-type MOS transistor. The transistors Tr201 and Tr202 are coupled in series. Specifically, the drain terminal of the transistor Tr201 is electrically coupled to the drain terminal of the transistor Tr202 via the resistors R201 and R202. In addition, the source terminal of the transistor Tr201 is electrically coupled to the first potential V11 (e.g., ground) via the transistor Tr203. In addition, the source terminal of the transistor Tr202 is electrically coupled to the second potential V12 (e.g., power supply voltage) via the transistor Tr204. In addition, a node N201 located between the resistor R201 and the resistor R202 is electrically coupled to the terminal N23.

The transistor Tr203 corresponds to the transistor Tr135 in the driver circuit 100 illustrated in FIG. 6, and is controlled on the basis of the enable signal EN to enter the conduction state. The enable signal EN is supplied to the base terminal. In addition, the transistor Tr204 has a configuration that is substantially similar to that of the transistor Tr135 in the driver circuit 100 illustrated in FIG. 6, and is controlled on the basis of the enable signal ENB to enter the conduction state. The enable signal ENB is supplied to the base terminal. In addition, the transistor Tr203 is controlled substantially as with the transistor Tr135. That is, it is sufficient if each of the transistors Tr203 and Tr204 is controlled to be in the conduction state at all times, for example, while the driver circuit 170 is in operation.

In such a configuration, the transistors Tr201 and Tr202 are driven on the basis of a signal inputted from the terminal N21. Specifically, a signal inputted from the terminal N21 is split by a node N202, and then supplied to the respective base terminals of the transistors Tr201 and Tr202. This causes a signal corresponding to the potential of the node N201 to be outputted to the outside of the driver circuit 170 via the terminal N23.

It is to be noted that the transistor Tr203 corresponds to an example of the “third transistor”, and the transistor Tr204 corresponds to an example of a “fourth transistor” in the driver circuit 170. That is, the transistor Tr201 corresponds to an example of a “first transistor”, and the transistor Tr202 corresponds to an example of a “second transistor”. In addition, one (i.e., terminal on the first potential V11 side) of the terminals including the source terminal and drain terminal of the first transistor that is electrically coupled to the third transistor corresponds to an example of the “second terminal”, and the other terminal corresponds to an example of the “first terminal”. Similarly, one (i.e., terminal on the second potential V12 side) of the terminals including the source terminal and drain terminal of the second transistor that is electrically coupled to the fourth transistor corresponds to an example of the “third terminal”, and the other terminal corresponds to an example of the “fourth terminal”. In addition, the base terminal of the first transistor corresponds to an example of a “control terminal” of the first transistor. Similarly, the base terminal of the second transistor corresponds to an example of a “control terminal” of the second transistor.

An example of a case where the driver circuit according to the modification example 4 is configured to have one input and one output has been described above with reference to FIG. 14 as an example of a configuration of the driver circuit.

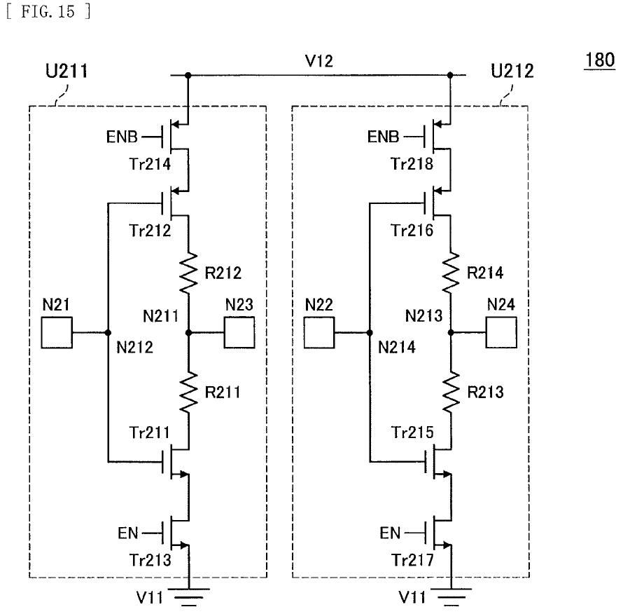

It is to be noted that it is also possible to configure one multi-input and multi-output driver circuit by coupling, in parallel, the driver circuits 170 each of which is illustrated in FIG. 14. For example, FIG. 15 is an explanatory diagram for describing another example of the configuration of the driver circuit according to the modification example 4. It is to be noted that the driver circuit illustrated in FIG. 15 is sometimes referred to as “driver circuit 180” to distinguish the driver circuit illustrated in FIG. 15 from the driver circuits according to the above-described embodiment and other modification examples.

As illustrated in FIG. 15, the driver circuit 180 is configured by coupling circuit groups U211 and U212 in parallel. Each of the circuit groups U211 and U212 corresponds to the driver circuit 170 illustrated in FIG. 14. That is, transistors Tr211 to Tr214, resistors R211 and R212, and the terminals N21 and N23 in the circuit group U211 respectively correspond to the transistors Tr201 to Tr204, the resistors R201 and R202, and the terminals N21 and N23 in the driver circuit 170. Similarly, transistors Tr215 to Tr218, resistors R213 and R214, and the terminals N22 and N24 in the circuit group U212 respectively correspond to the transistors Tr201 to Tr204, the resistors R201 and R202, and the terminals N21 and N23 in the driver circuit 170.

It is to be noted that an example of a case where a 2-input and 2-output driver circuit is configured by coupling the two driver circuits 180 in parallel has been described as the example illustrated in FIG. 15, but the number of driver circuits 180 coupled in parallel is not necessarily limited to two. For example, one driver circuit may be configured by coupling the three or more driver circuits 180 in parallel.

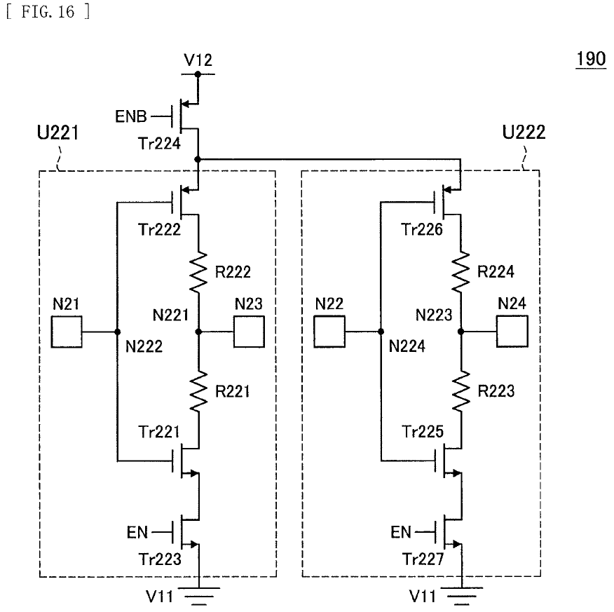

In addition, FIG. 16 is an explanatory diagram for describing another example of the configuration of the driver circuit according to the modification example 4. As the example illustrated in FIG. 16, an example of a case where the transistor Tr204 in the driver circuit 170 illustrated in FIG. 14 is shared between a plurality of circuit groups is demonstrated. It is to be noted that the driver circuit illustrated in FIG. 16 is sometimes referred to as “driver circuit 190” to distinguish the driver circuit illustrated in FIG. 16 from the driver circuits according to the above-described embodiment and other modification examples.

As illustrated in FIG. 16, the driver circuit 190 is configured by coupling circuit groups U221 and U222 in parallel and coupling a common transistor Tr224 to each of the circuit groups U221 and U222. Each of the circuit groups U221 and U222 corresponds to the components in the driver circuit 170 illustrated in FIG. 14 excluding the transistor Tr204. That is, transistors Tr221, Tr222, and Tr223, resistors R221 and R222, and the terminals N21 and N23 in the circuit group U221 respectively correspond to the transistors Tr201, Tr202, and Tr203, the resistors R201 and R202, and the terminals N21 and N23 in the driver circuit 170. Similarly, transistors Tr225, Tr226, and Tr227, resistors R223 and R224, and the terminals N22 and N24 in the circuit group U222 respectively correspond to the transistors Tr201, Tr202, and Tr203, the resistors R201 and R202, and the terminals N21 and N23 in the driver circuit 170. In addition, the transistor Tr224 corresponds to the transistor Tr204 in the driver circuit 170.

In addition, the number of circuit groups (e.g., circuit groups U221 and U222) coupled in parallel is not also limited in the example illustrated in FIG. 16. That is, one driver circuit may be configured by coupling three or more circuit groups in parallel, and sharing the transistor Tr224 between the three or more circuit groups.

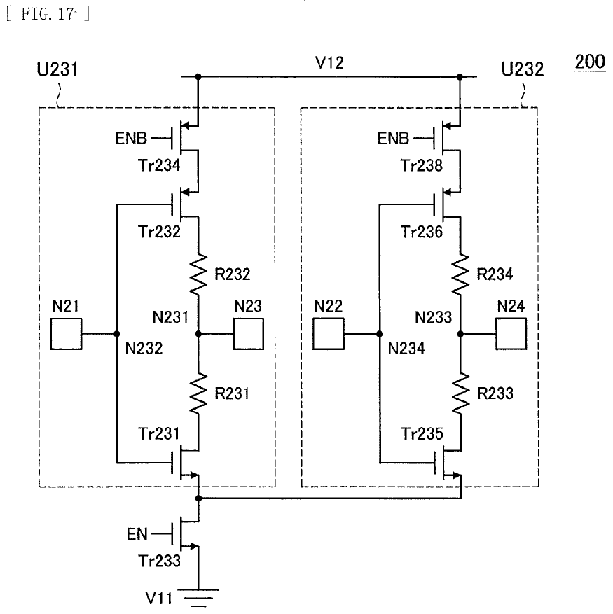

In addition, FIG. 17 is an explanatory diagram for describing another example of the configuration of the driver circuit according to the modification example 4. As the example illustrated in FIG. 17, an example of a case where the transistor Tr203 in the driver circuit 170 illustrated in FIG. 14 is shared between a plurality of circuit groups is demonstrated. It is to be noted that the driver circuit illustrated in FIG. 17 is sometimes referred to as “driver circuit 200” to distinguish the driver circuit illustrated in FIG. 17 from the driver circuits according to the above-described embodiment and other modification examples.

As illustrated in FIG. 17, the driver circuit 200 is configured by coupling circuit groups U231 and U232 in parallel and coupling a common transistor Tr233 to each of the circuit groups U231 and U232. Each of the circuit groups U231 and U232 corresponds to the components in the driver circuit 170 illustrated in FIG. 14 excluding the transistor Tr203. That is, transistors Tr231, Tr232, and Tr234, resistors R231 and R232, and the terminals N21 and N23 in the circuit group U231 respectively correspond to the transistors Tr201, Tr202, and Tr204, the resistors R201 and R202, and the terminals N21 and N23 in the driver circuit 170. Similarly, transistors Tr235, Tr236, and Tr238, resistors R233 and R234, and the terminals N23 and N24 in the circuit group U232 respectively correspond to the transistors Tr201, Tr202, and Tr204, the resistors R201 and R202, and the terminals N21 and N23 in the driver circuit 170. In addition, the transistor Tr233 corresponds to the transistor Tr203 in the driver circuit 170.

In addition, the number of circuit groups (e.g., circuit groups U231 and U232) coupled in parallel is not also limited in the example illustrated in FIG. 17. That is, one driver circuit may be configured by coupling three or more circuit groups in parallel, and sharing the transistor Tr233 between the three or more circuit groups.

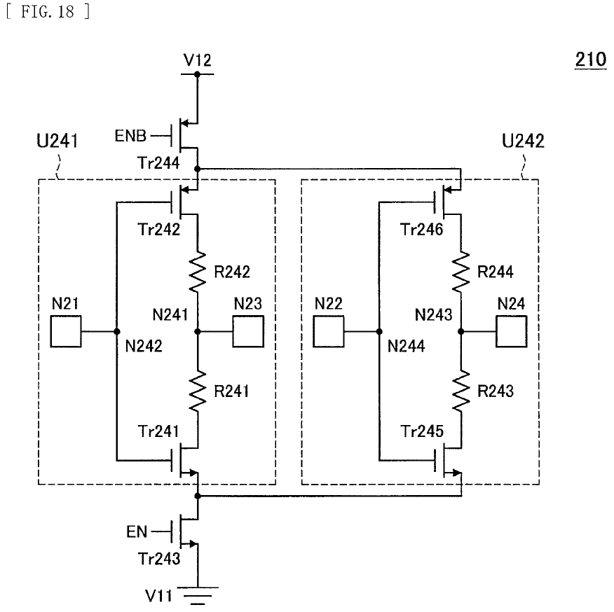

In addition, FIG. 18 is an explanatory diagram for describing another example of the configuration of the driver circuit according to the modification example 4. As the example illustrated in FIG. 18, an example of a case where the transistors Tr203 and Tr204 in the driver circuit 170 illustrated in FIG. 14 is shared between a plurality of circuit groups is demonstrated. It is to be noted that the driver circuit illustrated in FIG. 18 is sometimes referred to as “driver circuit 210” to distinguish the driver circuit illustrated in FIG. 18 from the driver circuits according to the above-described embodiment and other modification examples.

As illustrated in FIG. 18, the driver circuit 210 is configured by coupling circuit groups U241 and U242 in parallel and coupling common transistors Tr243 and Tr244 to each of the circuit groups U241 and U242. Each of the circuit groups U241 and U242 corresponds to the components in the driver circuit 170 illustrated in FIG. 14 excluding the transistors Tr203 and Tr204. That is, transistors Tr241 and Tr242, resistors R241 and R242, and the terminals N21 and N23 in the circuit group U241 respectively correspond to the transistors Tr201 and Tr202, the resistors R201 and R202, and the terminals N21 and N23 in the driver circuit 170. Similarly, transistors Tr245 and Tr246, resistors R243 and R244, and the terminals N23 and N24 in the circuit group U242 respectively correspond to the transistors Tr201 and Tr202, the resistors R201 and R202, and the terminals N21 and N23 in the driver circuit 170. In addition, the transistor Tr243 corresponds to the transistor Tr203 in the driver circuit 170. In addition, the transistor Tr244 corresponds to the transistor Tr204 in the driver circuit 170.

In addition, the number of circuit groups (e.g., circuit groups U241 and U242) coupled in parallel is not also limited in the example illustrated in FIG. 18. That is, one driver circuit may be configured by coupling three or more circuit groups in parallel, and sharing the transistors Tr243 and Tr244 between the three or more circuit groups.

Another example of a configuration of the driver circuit according to the present embodiment has been described above as the modification example 4, bringing into focus especially a case where a component corresponding to the transistor Tr153 is also provided on the second potential V12 side in the driver circuit 120 illustrated in FIG. 8.

### Modification Example 5

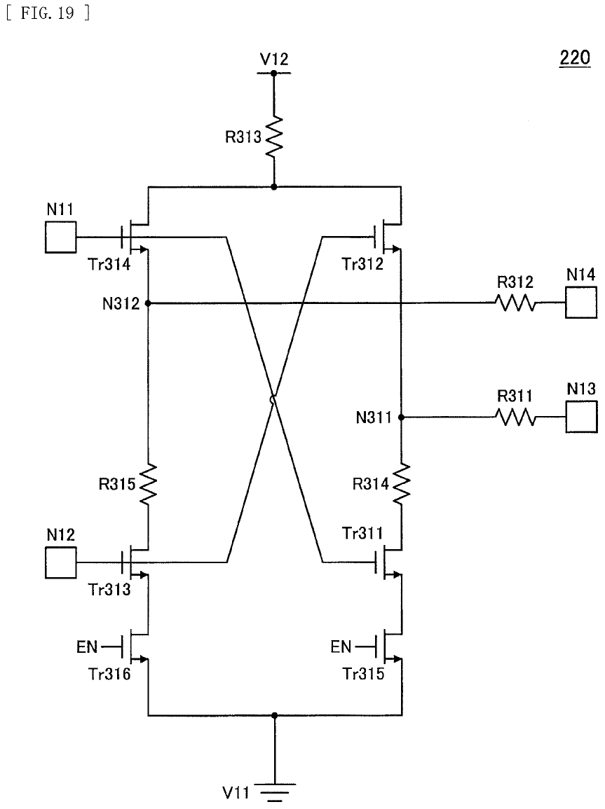

Next, a modification example of a configuration of the driver circuit 100 described with reference to FIG. 6 is described as a modification example 5. For example, FIG. 19 is an explanatory diagram for describing an example of a configuration of the driver circuit according to the modification example 5. It is to be noted that the driver circuit illustrated in FIG. 19 is sometimes referred to as “driver circuit 220” to distinguish the driver circuit illustrated in FIG. 19 from the driver circuits according to the above-described embodiment and other modification examples.

As illustrated in FIG. 19, the driver circuit 220 includes transistors Tr311 to Tr314, resistors R311 to R315, and transistors Tr315 and Tr316. The transistors Tr311 to Tr314 correspond to the transistors Tr131 to Tr134 in the driver circuit 100 illustrated in FIG. 6. In addition, the resistors R311 to R315 correspond to the resistors R131 to R135 in the driver circuit 100.

In the driver circuit 100 illustrated in FIG. 6, the circuit group including the transistors Tr131 and Tr132 and the resistor R134 and the circuit group including the transistors Tr133 and Tr134 and the resistor R135 share the transistor Tr135. In contrast, in the driver circuit 220, the circuit group including the transistors Tr311 and Tr312 and the resistor R314 and the circuit group including the transistors Tr313 and Tr314 and the resistor R315 are separately provided with respective components corresponding to the transistor Tr135.

Specifically, the source terminal of the transistor Tr311 is electrically coupled to the first potential V11 via the transistor Tr315. In addition, the source terminal of the transistor Tr313 is electrically coupled to the first potential V11 via the transistor Tr316. It is to be noted that each of the transistors Tr315 and Tr316 has a configuration that is substantially similar to that of the transistor Tr135 in the driver circuit 100, and is controlled on the basis of the enable signal EN to enter the conduction state. The enable signal EN is supplied to the base terminal. In addition, each of the transistors Tr315 and Tr316 is controlled substantially as with the transistor Tr135. That is, it is sufficient if each of the transistors Tr315 and Tr316 is controlled to be in the conduction state at all times, for example, while the driver circuit 220 is in operation.

A modification example of the configuration of the driver circuit 100 described with reference to FIG. 6 has been described above as the modification example 5 with reference to FIG. 19.

### Modification Example 6

Next, an example of a configuration that makes it possible to change a power supply voltage supplied to a driver circuit according to the present embodiment is described as a modification example 6. For example, FIG. 20 is an explanatory diagram for describing an example of a configuration of the driver circuit according to the modification example 6. It is to be noted that the driver circuit illustrated in FIG. 20 is sometimes referred to as “driver circuit 240” to distinguish the driver circuit illustrated in FIG. 20 from the driver circuits according to the above-described embodiment and other modification examples.

As illustrated in FIG. 20, the driver circuit 240 is configured by coupling a regulator U411 to a circuit group U401 as a power supply voltage. It is to be noted that the circuit group U401 corresponds to the portion of each of the driver circuits according to the above-described embodiment and respective modification examples. That is, it is possible to selectively apply the configurations of the driver circuits according to the above-described embodiment and respective modification examples to a configuration of the circuit group U401.

In the configuration as illustrated in FIG. 20, for example, the regulator U411 controls the level (amplitude level) of the power supply voltage, thereby making it possible to selectively change the level of a signal outputted from the circuit group U401 (i.e., driver circuit).

An example of a configuration that makes it possible to change a power supply voltage supplied to the driver circuit according to the present embodiment has been described above as the modification example 6 with reference to FIG. 20.

### 2.3. Application Examples

Next, application examples of the driver circuit according to the present embodiment are described.

### (Basic Configuration)

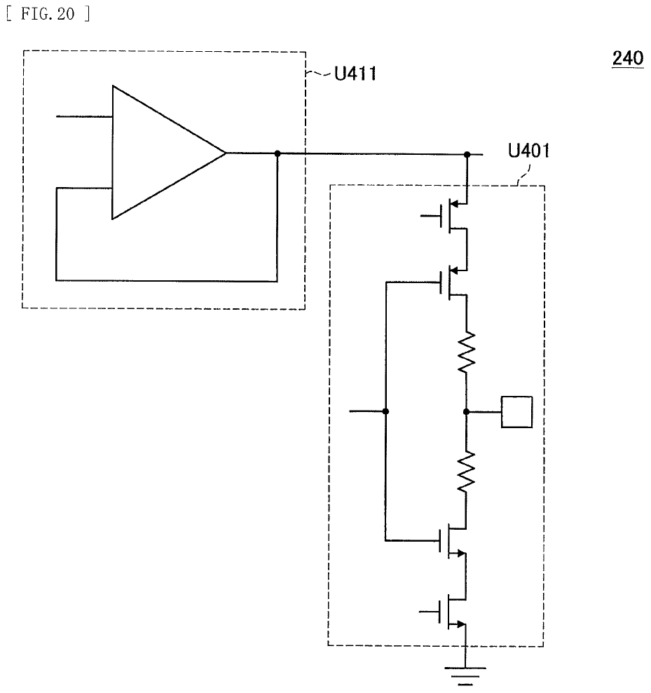

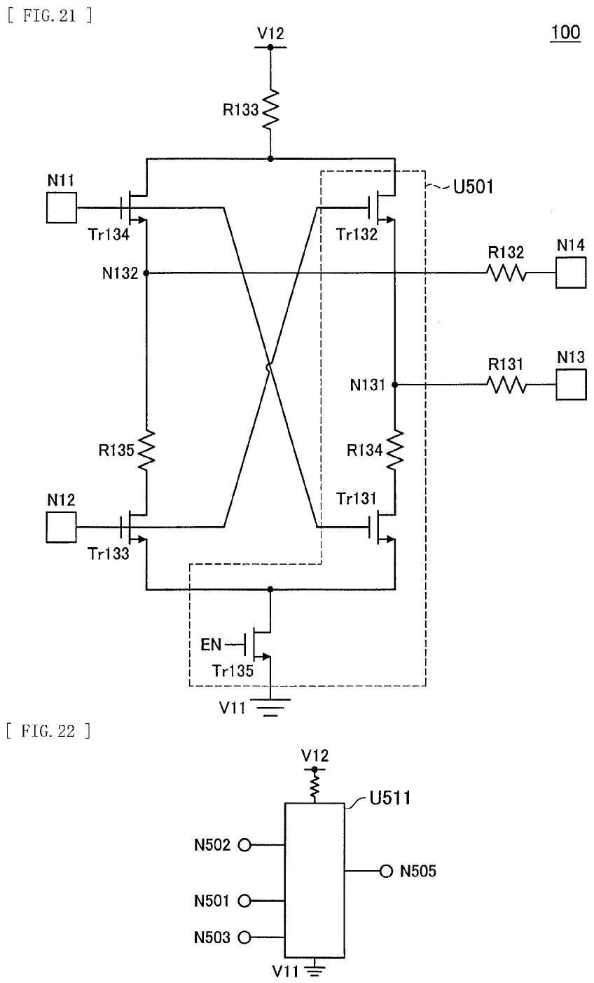

Before an application example of the driver circuit according to the present embodiment is described, an example of a unitary unit included in the driver circuit according to the present embodiment is first described with reference to FIGS. 21 and 22. Each of FIGS. 21 and 22 is an explanatory diagram for describing an application example of the driver circuit according to the present embodiment, and an explanatory diagram for describing an example of a unitary unit of the driver circuit.

FIG. 21 corresponds to an example of the circuit configuration of the driver circuit 100 according to the present embodiment described with reference to FIG. 6. It is assumed in this description that a portion (i.e., circuit group including the transistors Tr131, Tr132, and Tr135 and the resistor R134) of the driver circuit 100 illustrated in FIG. 21 that is indicated by a reference sign U501 is configured as a unitary unit. For example, FIG. 22 illustrates an example of a case where the circuit group indicated by the reference sign U501 in FIG. 21 is configured as a unitary unit U511.

A terminal N501 of the unitary unit U511 illustrated in FIG. 22 corresponds to the base terminal of the transistor Tr131 illustrated in FIG. 21. In addition, a terminal N502 corresponds to the base terminal of the transistor Tr132 illustrated in FIG. 21. In addition, a terminal N503 corresponds to the base terminal of the transistor Tr135 illustrated in FIG. 21. In addition, a terminal N505 corresponds to the node N131 of the driver circuit 100 illustrated in FIG. 21.

### Application Example 1

Next, an example of a case where the driver circuit 220 described with reference to FIG. 19 is configured by using the unitary unit U511 illustrated in FIG. 22 is described as an application example 1. For example, FIG. 23 is an explanatory diagram for describing an example of a configuration of the driver circuit according to the application example 1. It is to be noted that the driver circuit illustrated in FIG. 23 is sometimes referred to as “driver circuit 310” to distinguish the driver circuit illustrated in FIG. 23 from the driver circuits according to the above-described embodiment and modification examples, and the other application examples.

As illustrated in FIG. 23, the driver circuit 310 includes unitary units U511a and U511b. Each of the unitary units U511a and U511b corresponds to the unitary unit U511 illustrated in FIG. 22. It is to be noted that the terminals N11 to N14 in FIG. 23 correspond to the terminals N11 to N14 illustrated in FIG. 19. In addition, a terminal N15 corresponds to a terminal for supplying the enable signal EN to the base terminal of the transistor Tr315 illustrated in FIG. 19. Similarly, a terminal N16 corresponds to a terminal for supplying the enable signal EN to the base terminal of the transistor Tr316 illustrated in FIG. 19.

As described above, the use of the two unitary units U511 makes it possible to achieve the driver circuit 220 described with reference to FIG. 19.

An example of a case where the driver circuit 220 described with reference to FIG. 19 is configured by using the unitary unit U511 illustrated in FIG. 22 has been described above as the application example 1.

### Application Example 2

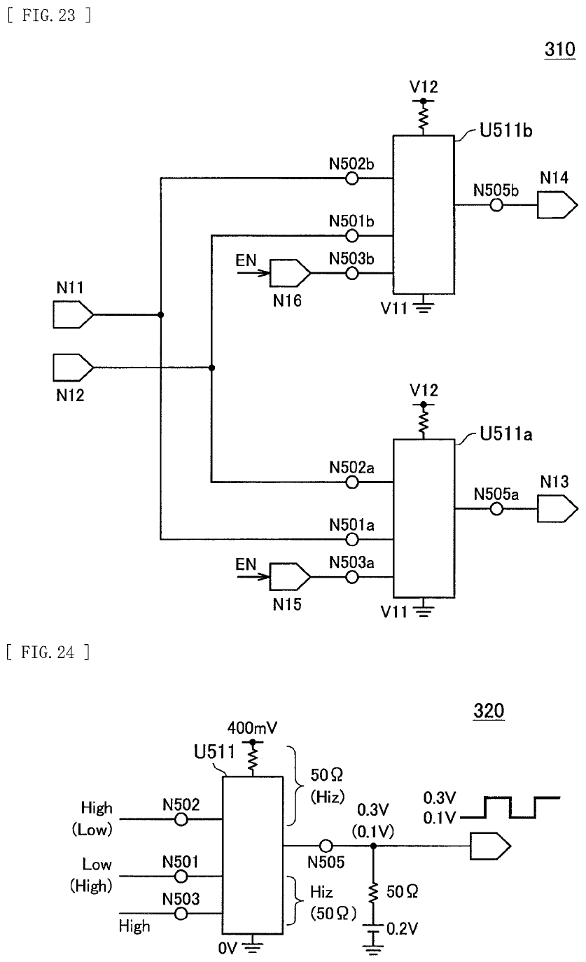

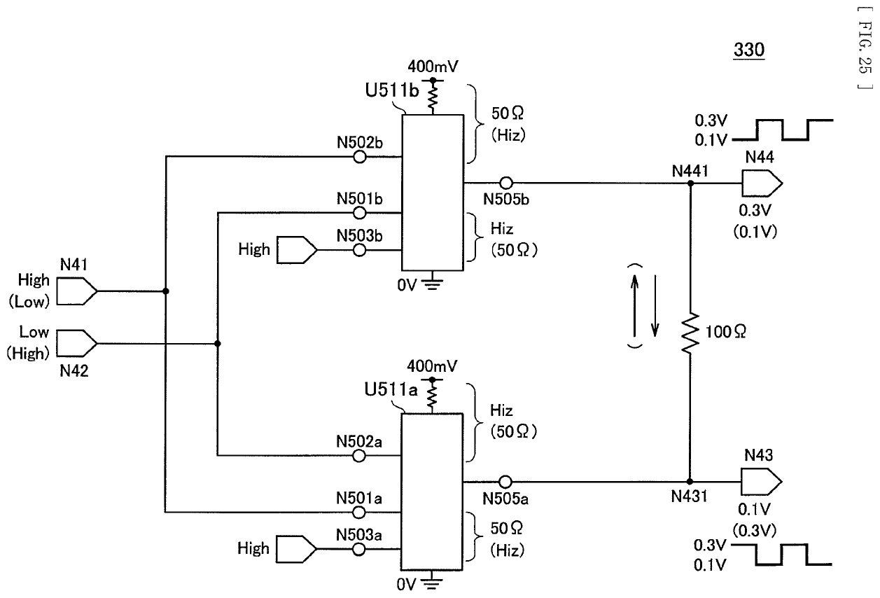

Next, an example of a configuration in a case where a driver circuit (2-input and 1-output driver circuit) having a single end configuration is achieved by using the unitary unit U511 illustrated in FIG. 22 is described as an application example 2. For example, FIG. 24 is an explanatory diagram for describing an example of a configuration of the driver circuit according to the application example 2. It is to be noted that the driver circuit illustrated in FIG. 24 is sometimes referred to as “driver circuit 320” to distinguish the driver circuit illustrated in FIG. 24 from the driver circuits according to the above-described embodiment and modification examples, and the other application examples.

The driver circuit 320 is configured to selectively switch the levels of signals inputted to the terminals N501 and N502 between high (High) and low (Low), thereby outputting a pulse signal from the terminal N505. Specifically, in the driver circuit 320, the first potential is set at 0 V (ground), and the second potential is set at 400 mV. The terminal N505 side of the unitary unit U511 is electrically coupled to the ground via a direct-current power supply of 0.2 V and a resistor of 50 Ω. In addition, while the driver circuit 320 is in operation, a high-level enable signal is inputted to the terminal N503 of the unitary unit U511.

In a case where a low-level signal is inputted to the terminal N501 in such a configuration, a high-level signal is inputted to the terminal N502. An adjustment is then made with the terminal N505 serving as a base point to cause the impedance of the first potential (0 V) side to be Hiz (high impedance) and cause the impedance of the second potential (400 mV) side to be 50 Ω. The potential of the terminal N505 is then 0.3 V, and a signal corresponding to the potential is outputted from the terminal N505.

In contrast, in a case where a high-level signal is inputted to the terminal N501, a low-level signal is inputted to the terminal N502. An adjustment is then made with the terminal N505 serving as a base point to cause the impedance of the first potential (0 V) side to be 50 Ω and cause the impedance of the second potential (400 mV) side to be Hiz (high impedance). The potential of the terminal N505 is then 0.1 V, and a signal corresponding to the potential is outputted from the terminal N505.

Such a configuration allows the driver circuit 320 illustrated in FIG. 24 to selectively switch the level of a signal outputted from the terminal N505 between the high level (0.3 V) and the low level (0.1 V) in accordance with to which of the terminals N501 and N502 a high-level signal is inputted.

An example of a configuration in a case where a (2-input and 1-output) driver circuit having a single end configuration is achieved by using the unitary unit U511 illustrated in FIG. 22 has been described above as the application example 2 with reference to FIG. 24.

### Application Example 3

Next, an example of a configuration in a case where a driver circuit having a differential configuration is achieved by using the unitary unit U511 illustrated in FIG. 22 is described as an application example 3. For example, FIG. 25 is an explanatory diagram for describing an example of a configuration of the driver circuit according to the application example 3. It is to be noted that the driver circuit illustrated in FIG. 25 is sometimes referred to as “driver circuit 330” to distinguish the driver circuit illustrated in FIG. 25 from the driver circuits according to the above-described embodiment and modification examples, and the other application examples.

As illustrated in FIG. 23, the driver circuit 330 includes the unitary units U511a and U511b. Each of the unitary units U511a and U511b corresponds to the unitary unit U511 illustrated in FIG. 22. A terminal N502a of the unitary unit U511a and a terminal N501b of the unitary unit U511b are electrically coupled to a terminal N42. In addition, a terminal N501a of the unitary unit U511a and a terminal N502b of the unitary unit U511b are electrically coupled to a terminal N41. A terminal N505a of the unitary unit U511a is electrically coupled to a terminal N43. A terminal N505b of the unitary unit U511b is electrically coupled to a terminal N44. The terminal N43 and the terminal N44 (i.e., node N431 and node N441) are electrically coupled via a resistor of 100 Ω. In addition, while the driver circuit 330 is in operation, high-level enable signals are inputted to the respective terminals N503 (i.e., terminals N503a and N503b) of the unitary units U511a and U511b.

In a case where a high-level signal is inputted to the terminal N41 in such a configuration, a low-level signal is inputted to the terminal N42. An adjustment is made on the unitary unit U511a side in this case with the terminal N505a serving as a base point to cause the impedance of the first potential (0 V) side to be 50 Ω and cause the impedance of the second potential (400 mV) side to be Hiz (high impedance). In addition, an adjustment is made on the unitary unit U511b side in this case with the terminal N505b serving as a base point to cause the impedance of the first potential (0 V) side to be Hiz (high impedance) and cause the impedance of the second potential (400 mV) side to be 50 Ω. The potential of the terminal N505a side is then 0.1 V, the potential of the terminal N505b side is 0.3 V, and a current flows from the node N441 to the node N431. In addition, the level of a signal outputted from the terminal N43 is low (0.1 V), and the level of a signal outputted from the terminal N44 is high (0.3 V).

In contrast, in a case where a low-level signal is inputted to the terminal N41, a high-level signal is inputted to the terminal N42. An adjustment is made on the unitary unit U511a side in this case with the terminal N505a serving as a base point to cause the impedance of the first potential (0 V) side to be Hiz (high impedance) and cause the impedance of the second potential (400 mV) side to be 50 Ω. In addition, an adjustment is made on the unitary unit U511b side in this case with the terminal N505b serving as a base point to cause the impedance of the first potential (0 V) side to be 50 Ω and cause the impedance of the second potential (400 mV) side to be Hiz (high impedance). The potential of the terminal N505a side is then 0.3 V, the potential of the terminal N505b side is 0.1 V, and a current flows from the node N431 to the node N441. In addition, the level of a signal outputted from the terminal N43 is high (0.3 V), and the level of a signal outputted from the terminal N44 is low (0.1 V).

An example of a configuration in a case where a driver circuit having a differential configuration is achieved by using the unitary unit U511 illustrated in FIG. 22 has been described above as the application example 3 with reference to FIG. 25.

### Application Example 4

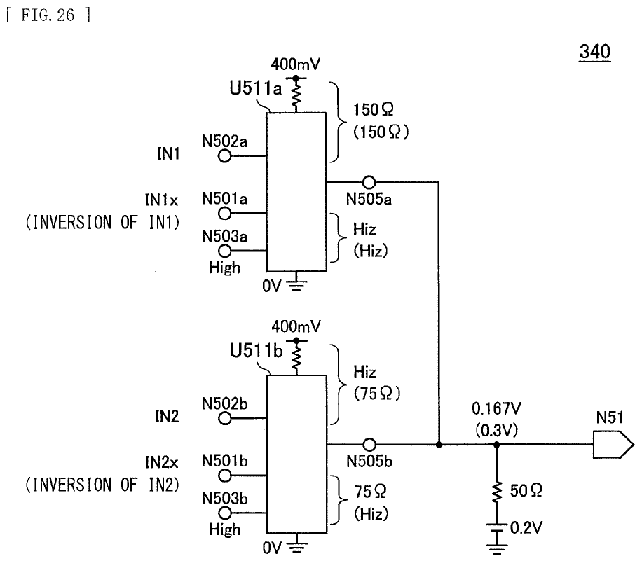

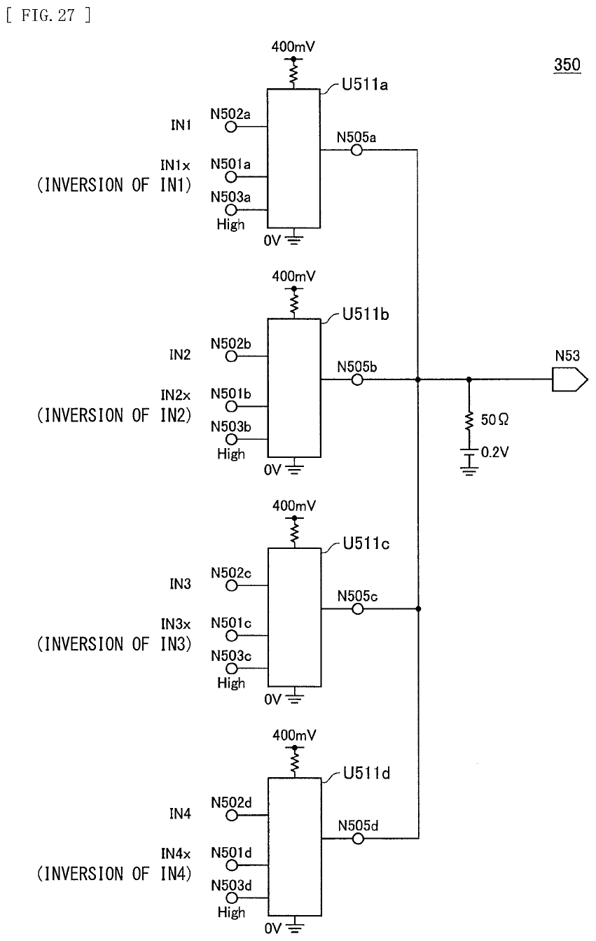

Next, an example of a configuration in a case where a multi-input and 1-output driver circuit intended for multilevel transmission is achieved by using the unitary unit U511 illustrated in FIG. 22 is described as an application example 4. For example, FIG. 26 is an explanatory diagram for describing an example of a configuration of a driver circuit according to the application example 4, and illustrates an example of a 2-input and 1-output driver circuit intended for 4-level transmission. It is to be noted that the driver circuit illustrated in FIG. 26 is sometimes referred to as “driver circuit 340” to distinguish the driver circuit illustrated in FIG. 26 from the driver circuits according to the above-described embodiment and modification examples, and the other application examples.

The driver circuit 340 includes the unitary units U511a and U511b. Each of the unitary units U511a and U511b corresponds to the unitary unit U511 illustrated in FIG. 22. In the unitary unit U511a, an input signal IN1 is inputted to the terminal N502a, and an input signal INlx obtained by inverting the input signal IN1 is inputted to the terminal N501a. In addition, in the unitary unit U511b, an input signal IN2 is inputted to the terminal N502b, and an input signal IN2x obtained by inverting the input signal IN2 is inputted to the terminal N501b. It is to be noted that the input signals IN1 and IN2 are different signals. The respective terminals N505 (i.e., terminals N505a and N505b) of the unitary units U511a and U511b are electrically coupled to a terminal N51. In addition, the terminal N505a side of the unitary unit U511a and the terminal N505a side of the unitary unit U511b are electrically coupled to the ground via a direct-current power supply of 0.2 V and a resistor of 50 Ω. In addition, while the driver circuit 340 is in operation, high-level enable signals are inputted to the respective terminals N503 (i.e., terminals N503a and N503b) of the unitary units U511a and U511b.

The unitary unit U511a is adjusted with the terminal N505a serving as a base point to cause the impedance of the first potential (0 V) side to be Hiz (high impedance) and cause the impedance of the second potential (400 mV) side to be 150 Ω in a case where the level of the input signal IN1 is high (High). In addition, the unitary unit U511a is adjusted with the terminal N505a serving as a base point to cause the impedance of the first potential (0 V) side to be 150 Ω and cause the impedance of the second potential (400 mV) side to be Hiz (high impedance) in a case where the level of the input signal IN1 is low (Low).

The unitary unit U511b is adjusted with the terminal N505b serving as a base point to cause the impedance of the first potential (0 V) side to be Hiz (high impedance) and cause the impedance of the second potential (400 mV) side to be 75 Ω in a case where the level of the input signal IN2 is high (High). In addition, the unitary unit U511b is adjusted with the terminal N505b serving as a base point to cause the impedance of the first potential (0 V) side to be 75 Ω and cause the impedance of the second potential (400 mV) side to be Hiz (high impedance) in a case where the level of the input signal IN2 is low (Low).

The configuration as described above causes the level of a signal (that is also referred to as “output signal OUT” below) outputted from the terminal N51 to be selectively switched within the range of the four stages of a level 0 to a level 3 in accordance with a combination of the respective levels of the input signals IN1 and IN2. For example, Table 1 below indicates an example of the relationship between the input signals IN1 and IN2 and the output signal OUT.

### [Table 1]

TABLE 1
Relationship between input signals and an output signal

| input signal IN2 | input signal IN1 | output signal OUT | | Level |
|---|---|---|---|---|
| Low | Low | 0.1 | V | 0 |
| Low | High | 0.167 | V | 1 |
| High | Low | 0.233 | V | 2 |
| High | High | 0.3 | V | 3 |

It is to be noted that the setting of impedance in each unitary unit U511 is merely an example, and the setting may be changed as appropriate to obtain the output signal OUT at a desired level.

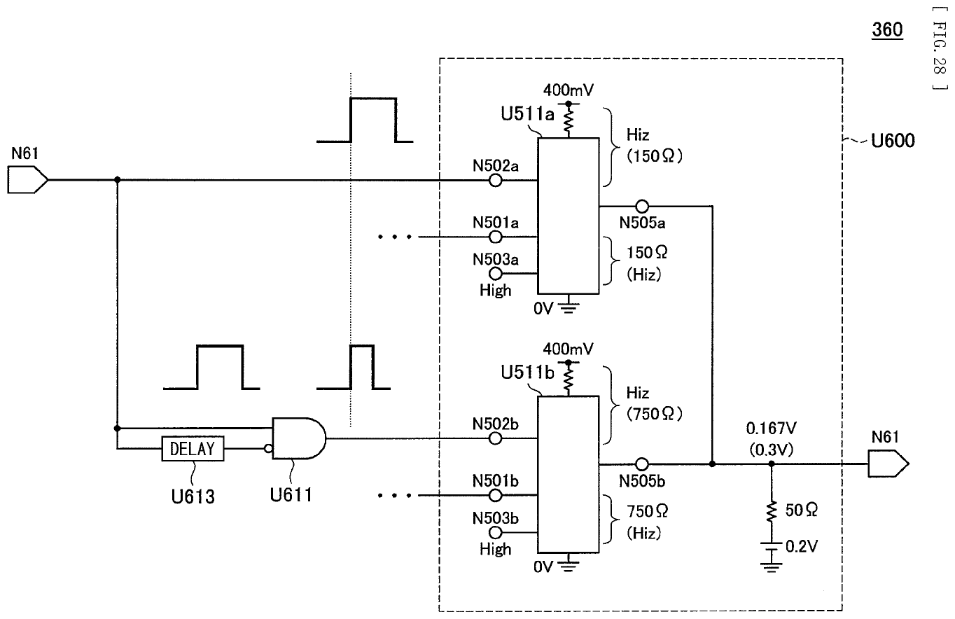

In addition, it is also possible in the above to configure the driver circuit according to the application example 4 as a driver circuit usable for multilevel transmission exceeding four levels by increasing the number of unitary units U511. For example, FIG. 27 is an explanatory diagram for describing another example of a configuration of a driver circuit according to the application example 4, and illustrates an example of a 4-input and 1-output driver circuit intended for 16-level transmission. It is to be noted that the driver circuit illustrated in FIG. 26 is sometimes referred to as “driver circuit 350” to distinguish the driver circuit illustrated in FIG. 26 from the driver circuits according to the above-described embodiment and modification examples, and the other application examples.

Specifically, the driver circuit 350 includes the unitary units U511a to U511d. Each of the unitary units U511a to U511dcorresponds to the unitary unit U511 illustrated in FIG. 22. The input signals IN1 to IN4 different from each other are respectively inputted to the unitary units U511a to U511d. A signal obtained by inverting the input signal inputted to a terminal 502 is then inputted to a terminal 501 of each unitary unit U511. As a specific example, in the unitary unit U511a, the input signal IN1 is inputted to the terminal N502a, and the input signal INlx obtained by inverting the input signal IN1 is inputted to the terminal N501a. In addition, the unitary units U511b to U511dare also similar to the case of the unitary unit U511a except that input signals to be inputted are different. The respective terminals N505 (i.e., terminals N505a to N505d) of the unitary units U511a to U511dare electrically coupled to a terminal N53. In addition, the terminal N505 side of each of the unitary units U511a to U511dis electrically coupled to the ground via a direct-current power supply of 0.2 V and a resistor of 50 Ω. In addition, while the driver circuit 350 is in operation, high-level enable signals are inputted to the respective terminals N503 (i.e., terminals N503a to N503d) of the unitary units U511a to U511d.

It is sufficient if the impedance of the first potential (0 V) side and the impedance of the second potential (400 mV) side are adjusted as appropriate with the terminal N505 of each of the unitary units U511a to U511dserving as a base point in accordance with the level of the output signal OUT to be outputted in the configuration described above.

The configuration as described above allows the level of the output signal OUT outputted from the terminal N53 to be selectively switched within the range of the sixteen stages of the level 0 to a level 15 in accordance with a combination of the respective levels of the input signals IN1 to IN4.

An example of a configuration in a case where a multi-input and 1-output driver circuit intended for multilevel transmission is achieved by using the unitary unit U511 illustrated in FIG. 22 has been described above as the application example 4 with reference to FIGS. 26 and 27.

### Application Example 5

Next, an example of a configuration in a case where a driver circuit in a case where pre-emphasis is used is achieved by using the unitary unit U511 illustrated in FIG. 22 is described as an application example 5. In a case where transmission loss in high frequency may occur in a transmission path between a transmitter and a receiver, modulation technology referred to as pre-emphasis is sometimes used to improve a frequency characteristic of a signal received on the receiver side. In the present application example, an example of a case where a driver circuit that is able to use pre-emphasis is configured on the basis of a driver circuit intended for the multilevel transmission described above is described.

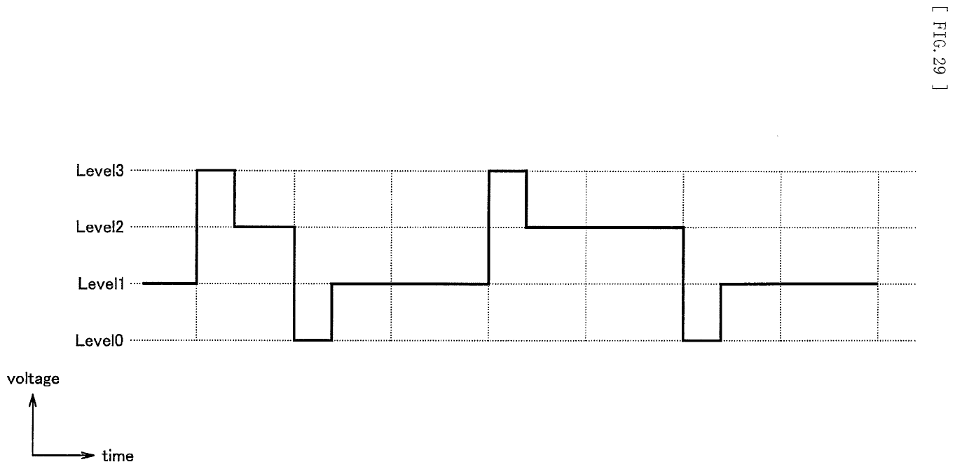

For example, FIG. 28 is an explanatory diagram for describing an example of a configuration of the driver circuit according to the application example 5, and illustrates an example of a driver circuit in a case where four levels are used for 2-level transmission as pre-emphasis. It is to be noted that the driver circuit illustrated in FIG. 28 is sometimes referred to as “driver circuit 360” to distinguish the driver circuit illustrated in FIG. 28 from the driver circuits according to the above-described embodiment and modification examples, and the other application examples. In addition, in FIG. 28, a portion indicated by a reference sign U600 is substantially similar to the driver circuit 340 described with reference to FIG. 26, and detailed description is thus omitted. In addition, inverted inputs (i.e., input signals IN1x and IN2x in FIG. 26) to the terminal N501 of each unitary unit U511 are not illustrated in the example illustrated in FIG. 28 to facilitate the understanding of a feature of the driver circuit 360 according to the present application example.

As illustrated in FIG. 28, an input signal inputted from a terminal N61 is split in the driver circuit 360, and a portion of the signals is inputted to the terminal N502a of the unitary unit U511a.

In addition, among signals split from the input signal, another signal different from the signal inputted to the terminal N502a is inputted to the terminal N502b of the unitary unit U511b via an AND circuit U611. Specifically, the other partial signal is further split, and one of the split signals is inputted to one of the input terminals of the AND circuit U611 as it is. In addition, the other of the split signals is delayed and then inverted by a delay circuit U613. The inverted signal is inputted to the other input terminal of the AND circuit U611. The AND circuit U611 outputs a signal corresponding to the logical product of the two inputted signals. That is, the signal outputted from the AND circuit U611 is inputted to the terminal N502b of the unitary unit U511b.

Here, an example of an output signal outputted from the terminal N61 of the driver circuit 360 illustrated in FIG. 28 is described with reference to FIG. 29. FIG. 29 is an explanatory diagram for describing an example of an output of the driver circuit according to the present application example. In FIG. 29, the horizontal axis represents time, and the vertical axis represents voltage values. As illustrated in FIG. 29, the driver circuit 360 illustrated in FIG. 28 uses the level 3 among the four levels of the level 0 to the level 3 as pre-emphasis in transmitting the high level of the two levels, and uses the level 0 as pre-emphasis in transmitting the low level of the two levels.

It is to be noted that the amount of delay imparted by the delay circuit U613 to an input signal is not limited in particular. As a specific example, the delay circuit U613 may impart a delay of one UI (Unit Interval) to an input signal. In addition, the number of unitary units U511 included in the driver circuit 360 is not also limited in particular. That is, the driver circuit 360 may include the three or more unitary units U511. In addition, a combination of a plurality of levels may be used as pre-emphasis. In addition, the driver circuit 360 may be configured as a so-called differential configuration.

An example of a configuration in a case where a driver circuit in a case where pre-emphasis is used is achieved by using the unitary unit U511 illustrated in FIG. 22 has been described above as the application example 5 with reference to FIGS. 28 and 29.

### (Supplement)

It is to be noted that a configuration of a unitary unit is not necessarily limited to the examples described with reference to FIGS. 21 and 22. For example, it is also possible to configure the driver circuit 120 illustrated in FIG. 8, the driver circuit 150 illustrated in FIG. 11, or the driver circuit 170 illustrated in FIG. 14 as a unitary unit. In addition, it is also possible to configure multi-input and multi-output or multi-input and 1-output driver circuit (i.e., m-input and n-output (where m and n each represent a positive integer) driver circuit) by combining a plurality of the unitary units as in the examples described with reference to FIGS. 23 to 29.

### <<3. Conclusion>>

As described above, the driver circuit according to the embodiment of the present disclosure includes a first transistor, a second transistor, a third transistor, and an output terminal. The first transistor includes a control terminal, a first terminal, and a second terminal. The second transistor is coupled to the above-described first terminal of the above-described first transistor in series via a predetermined load. The third transistor is coupled to the above-described second terminal of the above-described first transistor in series to be interposed between the first transistor and any one of potentials including a first potential and a second potential that are different from each other. The above-described third transistor is controlled in such a configuration to be in a conduction state while at least the first transistor and the second transistor are in operation.

In this way, the driver circuit according to the present embodiment has two transistors (i.e., first transistor and third transistor) interposed between the output terminal and the first potential (e.g., ground). This allows the driver circuit according to the present embodiment to considerably increase ESD resistance as compared with a case where one transistor is interposed between the output terminal and the first potential. In addition, the driver circuit according to the present embodiment is configured to have a load on the output terminal side on the basis of the first transistor. Such a configuration makes the load visible to the output terminal side irrespective of the influence of the parasitic capacitance of the first transistor even in a situation in which a high frequency signal is used. This allows the driver circuit according to the present embodiment to be less likely to have a potential of the output terminal polarized even in a situation in which a high frequency signal is used, and further reduce return loss as compared with a case where the first transistor is provided with a load on an opposite side (i.e., first potential side) to the output terminal. That is, the driver circuit according to the present embodiment makes it possible to achieve both reduction in return loss and increase in ESD resistance.

A preferred embodiment(s) of the present disclosure has/have been described above in detail with reference to the accompanying drawings, but the technical scope of the present disclosure is not limited to such an embodiment(s). It is apparent that a person having ordinary skill in the art of the present disclosure may arrive at various alterations and modifications within the scope of the technical idea described in the appended claims, and it is understood that such alterations and modifications naturally fall within the technical scope of the present disclosure.

In addition, the effects described herein are merely illustrative and exemplary, and not limitative. That is, the technology according to the present disclosure may exert other effects that are apparent to those skilled in the art from the description herein, in addition to the above-described effects or in place of the above-described effects.

It is to be noted that the following configurations also fall within the technical scope of the present disclosure.
(1)

A driver circuit including:

a first transistor including a control terminal, a first terminal, and a second terminal;

a second transistor coupled to the first terminal of the first transistor in series via a predetermined load;

a third transistor coupled to the second terminal of the first transistor in series to be interposed between the first transistor and any one of potentials including a first potential and a second potential, the first potential and the second potential being different from each other; and

an output terminal coupled between the second transistor and the load, in which

the third transistor is controlled to be in a conduction state while at least the first transistor and the second transistor are driven.
(2)

The driver circuit according to (1), in which

the second transistor includes a third terminal, a fourth terminal, and a control terminal,

a fourth terminal of the second transistor is coupled to the first terminal of the first transistor via the load, and

the third terminal of the second transistor is electrically coupled to another potential different from the one of the potentials including the first potential and the second potential.
(3)

The driver circuit according to (2), including a plurality of circuit groups each including at least the first transistor, the second transistor, and the output terminal, in which

in each of a plurality of the circuit groups,
the second terminal of the first transistor is electrically coupled to the one of the potentials via the third transistor, and
the third terminal of the second transistor is electrically coupled to the other potential.
(4)

The driver circuit according to (3), in which

each of a plurality of the circuit groups includes the third transistor, and

the second terminal of the first transistor of each of a plurality of the circuit groups is electrically coupled to the one of the potentials via the third transistor included in the circuit group.
(5)

The driver circuit according to (3), in which the second terminal of the first transistor of each of a plurality of the circuit groups is electrically coupled to the one of the potentials via the third transistor that is common.
(6)

The driver circuit according to any one of (3) to (5), in which at least two or more circuit groups among a plurality of the circuit groups have different potential differences between the respective first potentials and the respective output terminals.
(7)

The driver circuit according to (2), including a fourth transistor coupled to the third terminal of the second transistor in series to be interposed between the second transistor and the other potential.
(8)

The driver circuit according to (7), including a plurality of circuit groups each including at least the first transistor, the second transistor, and the output terminal, in which

in each of a plurality of the circuit groups,
the second terminal of the first transistor is electrically coupled to the one of the potentials via the third transistor, and
the third terminal of the second transistor is electrically coupled to the other potential via the fourth transistor.
(9)

The driver circuit according to (8), in which

each of a plurality of the circuit groups includes the fourth transistor, and the third terminal of the second transistor of each of a plurality of the circuit groups is electrically coupled to the other potential via the fourth transistor included in the circuit group.
(10)

The driver circuit according to (8), in which the third terminal of the second transistor of each of a plurality of the circuit groups is electrically coupled to the other potential via the fourth transistor that is common.
(11)

The driver circuit according to any one of (2) to (10), in which common input signals are inputted to the respective control terminals of the first transistor and the second transistor.
(12)

The driver circuit according to any one of (2) to (10), in which input signals different from each other are inputted to the respective control terminals of the first transistor and the second transistor.
(13)

The driver circuit according to any one of (1) to (12), in which the first transistor and the second transistor each include a N-type or P-type transistor.
(14)

The driver circuit according to any one of (1) to (12), in which

the first transistor includes one of transistors including an N-type transistor and a P-type transistor, and

the second transistor includes another transistor different from the one of the transistors including the N-type transistor and the P-type transistor.
(15)

The driver circuit according to any one of (1) to (14), in which at least one of the first potential or the second potential is controlled by a predetermined control circuit.

### REFERENCE SIGNS LIST

100 driver circuit
Tr131 transistor

Tr132 transistor
Tr133 transistor
Tr134 transistor
Tr135 transistor
R131 resistor
R132 resistor
R133 resistor
R134 resistor
R135 resistor
V11 first potential
V12 second potential
900 receiver

1. A driver circuit comprising:
a first transistor including a control terminal, a first terminal, and a second terminal;
a second transistor coupled to the first terminal of the first transistor in series via a predetermined load;
a third transistor coupled to the second terminal of the first transistor in series to be interposed between the first transistor and any one of potentials including a first potential and a second potential, the first potential and the second potential being different from each other; and
an output terminal coupled between the second transistor and the load, wherein
the third transistor is controlled to be in a conduction state while at least the first transistor and the second transistor are driven.

2. The driver circuit according to claim 1, wherein
the second transistor includes a third terminal, a fourth terminal, and a control terminal,
a fourth terminal of the second transistor is coupled to the first terminal of the first transistor via the load, and
the third terminal of the second transistor is electrically coupled to another potential different from the one of the potentials including the first potential and the second potential.

3. The driver circuit according to claim 2, comprising a plurality of circuit groups each including at least the first transistor, the second transistor, and the output terminal, wherein
in each of a plurality of the circuit groups,
the second terminal of the first transistor is electrically coupled to the one of the potentials via the third transistor, and
the third terminal of the second transistor is electrically coupled to the other potential.

4. The driver circuit according to claim 3, wherein
each of a plurality of the circuit groups includes the third transistor, and
the second terminal of the first transistor of each of a plurality of the circuit groups is electrically coupled to the one of the potentials via the third transistor included in the circuit group.

5. The driver circuit according to claim 3, wherein the second terminal of the first transistor of each of a plurality of the circuit groups is electrically coupled to the one of the potentials via the third transistor that is common.

6. The driver circuit according to claim 3, wherein at least two or more circuit groups among a plurality of the circuit groups have different potential differences between the respective first potentials and the respective output terminals.

7. The driver circuit according to claim 2, comprising a fourth transistor coupled to the third terminal of the second transistor in series to be interposed between the second transistor and the other potential.

8. The driver circuit according to claim 7, comprising a plurality of circuit groups each including at least the first transistor, the second transistor, and the output terminal, wherein
in each of a plurality of the circuit groups,
the second terminal of the first transistor is electrically coupled to the one of the potentials via the third transistor, and
the third terminal of the second transistor is electrically coupled to the other potential via the fourth transistor.

9. The driver circuit according to claim 8, wherein
each of a plurality of the circuit groups includes the fourth transistor, and
the third terminal of the second transistor of each of a plurality of the circuit groups is electrically coupled to the other potential via the fourth transistor included in the circuit group.

10. The driver circuit according to claim 8, wherein the third terminal of the second transistor of each of a plurality of the circuit groups is electrically coupled to the other potential via the fourth transistor that is common.

11. The driver circuit according to claim 2, wherein common input signals are inputted to the respective control terminals of the first transistor and the second transistor.

12. The driver circuit according to claim 2, wherein input signals different from each other are inputted to the respective control terminals of the first transistor and the second transistor.

13. The driver circuit according to claim 1, wherein the first transistor and the second transistor each include a N-type or P-type transistor.

14. The driver circuit according to claim 1, wherein
the first transistor includes one of transistors including an N-type transistor and a P-type transistor, and
the second transistor includes another transistor different from the one of the transistors including the N-type transistor and the P-type transistor.

15. The driver circuit according to claim 1, wherein at least one of the first potential or the second potential is controlled by a predetermined control circuit.
